(19) United States
(12) Patent Application Publication
(10) Pub. No.: US 2025/0386428 A1
(43) Pub. Date: Dec. 18, 2025

(54) SUBSTRATE ASSEMBLY AND ELECTRONIC DEVICE

(71) Applicant: PanelSemi Corporation, New Taipei City (TW)

(72) Inventors: Tang-Chin HUNG, New Taipei City (TW); Hsien-Te CHEN, New Taipei City (TW); Chin-Tang LI, New Taipei City (TW)

(21) Appl. No.: 19/239,033

(22) Filed: Jun. 16, 2025

Related U.S. Application Data
(60) Provisional application No. 63/660,058, filed on Jun. 14, 2024.

(51) Int. Cl. H05K 1/02; H01L 25/065; H01L 25/18; H05K 1/11; H10B 80/00; H10D 80/30

(52) U.S. Cl. CPC H05K 1/0274; H01L 25/0652; H01L 25/18; H05K 1/115; H05K 2201/068; H05K 2201/09227; H05K 2201/096; H10B 80/00; H10D 80/30

(57) ABSTRACT

The present invention provides a substrate assembly including a substrate, a composite-layered structure and a bonding layer. The composite-layered structure defines a conjunction plane, and one or more conductive-trace layers and one or more optical-trace layers are arranged either or both of over and beneath the conjunction plane; wherein the optical-trace layer defines a plurality of optical traces, and the conductive-trace layer defines a plurality of conductive traces. The bonding layer is adhesive between the substrate and the composite-layered structure. The present invention also provides an electronic device including a substrate assembly and a plurality of semiconductor components arranged on the composite-layered structure of the substrate assembly; wherein some of the semiconductor components are electrically connected to the conductive-trace layers, and some of the semiconductor components are optically communicated with the optical-trace layers.

### CROSS REFERENCE TO RELATED APPLICATIONS

This Non-provisional Application claims the benefit of U.S. Provisional Application with Ser. No. 63/660,058 filed on Jun. 14, 2024 (“the '058 provisional”), the entire contents of which are incorporated herein by reference.

The entire disclosure of U.S. Provisional Application No. 63/585,746 filed on Sep. 27, 2023 (“the '746 provisional”), and U.S. Provisional Application No. 63/631,109 filed on Apr. 8, 2024 (“the '109 provisional”) are incorporated herein by reference.

### BACKGROUND

### Technology Field

The disclosure relates to an electronic device applied with a hybrid substrate.

### Description of Related Art

Conventional substrate packaging technologies are mostly limited to achieving electrical connections and face significant challenges in integrating high-performance optical communication. Attempts to combine both often result in complex manufacturing processes and high costs, making it difficult to meet industry demands for high bandwidth, low loss, and high-density packaging. Existing optoelectronic hybrid solutions are also constrained by limited process flexibility and lack the capability for heterogeneous multi-material integration and high-density stacking.

### SUMMARY

The present invention overcomes these limitations by adopting a heterogeneous integration design concept, enabling the realization of coplanar or stacked arrangements of conductive-trace layers and optical layers on a single or multi-layer substrate. As a result, it supports high-density electro-optical hybrid communication and highly reliable packaging, while offering diverse process flexibility and material choices, thus significantly enhancing system integration and application versatility.

One or more exemplary embodiments of this disclosure are to provide a substrate assembly, an electronic device and an electronic apparatus applied with the substrate assembly, that incorporates heterogeneous architecture for adapting to the semiconductor industry with the high computing performance, high-efficiency and budget manufacture.

According to one aspect of the present disclosure, a substrate assembly is provided. The substrate assembly comprises a substrate; a composite-layered structure defining a conjunction plane, and one or more conductive-trace layers and one or more optical-trace layers arranged either or both of over and beneath the conjunction plane, wherein the optical-trace layer defines a plurality of optical traces, and the conductive-trace layer defines a plurality of conductive traces; and a bonding layer adhesive between the substrate and the composite-layered structure.

In some embodiments, the one or more conductive-trace layers and the one or more optical-trace layers are mixed in a coplanar manner.

In some embodiments, either of the conductive-trace layer and the optical-trace layer is over the conjunction plane, and the other is beneath the conjunction plane.

In some embodiments, some of the conductive-trace layers construct a redistribution layer (RDL).

In some embodiments, the conductive trace defines a trace width, and at least part of the trace width is no greater than 10 μm.

In some embodiments, the conductive trace defines a trace width, and at least part of the trace width is no greater than 2 μm.

In some embodiments, at least part of the optical traces is formed of waveguides.

In some embodiments, the waveguides are planar, strip, or ridge waveguides.

In some embodiments, a supportive-substrate layer is defined along the conjunction plane.

In some embodiments, the conductive-trace layer(s) is/are arranged over the supportive-substrate layer; the optical-trace layer(s) is/are arranged over the supportive-substrate layer; or the conductive-trace layer(s) and the optical-trace layer(s) are mixed in a coplanar manner and arranged over the supportive-substrate layer.

In some embodiments, the supportive-substrate layer comprises adhesion, polyimide, or a combination thereof.

In some embodiments, the substrate is at least 100 mm by 100 mm in planar size.

In some embodiments, the substrate is a glass substrate, a ceramic substrate, a bismaleimide triazin laminated (BT) substrate, a fiberglass-reinforced epoxy-laminated (FR4) substrate, a build-up film, a Rogers substrate, a polyimide substrate, or any combination containing any substrate mentioned above.

In some embodiments, a plurality of passages are defined, which are formed in either or both of the conductive-trace layers and the optical-trace layers for electrical connection or optical communication in a perpendicular direction to the substrate, wherein the passages pass through the bonding layer or further through the substrate.

In some embodiments, a plurality of passages are defined, which are formed in either or both of the conductive-trace layers and the optical-trace layers for electrical connection or optical communication in a perpendicular direction to the substrate; wherein the passages pass through the bonding layer and the supportive-substrate layer, or further through the substrate.

In some embodiments, one or more optical engines are arranged on a corresponding one of the optical-trace layers, wherein some of the optical traces of the optical-trace layer extend in a first direction along the composite-layered structure, and some of the optical traces extend in a second direction; the first direction is non-parallel with the second direction; some of the optical engines control the optical traces in either or both of the first direction and the second direction.

In some embodiments, one or more optical engines are arranged on corresponding ones of the optical-trace layers in a respective manner, wherein some of the optical traces of one of the optical-trace layers extend in a first direction, and some of the optical traces of another optical-trace layer extend in a second direction; the first direction is non-parallel with the second direction; some of the optical engines control either or all of the input and output of the optical traces in both the first direction and the second direction; the optical engines are provided with the corresponding optical-trace layers with electrical connection or optical communication.

In some embodiments, some of the optical engines control the optical traces in a perpendicular direction to the composite-layered structure.

In some embodiments, the optical engine includes one or more photoelectric conversion members and one or more optical modulators.

In some embodiments, the optical engine includes one or more optical trace steering components.

In some embodiments, the substrate, the optical-trace layers, and the conductive-trace layers define a coefficient of thermal expansion, and a difference of CTE between any of the substrate, the optical-trace layers, and the conductive-trace layers is no greater than 30 ppm/° C.

In some embodiments, the substrate, the optical-trace layers, the conductive-trace layers, and the supportive-substrate layer define a coefficient of thermal expansion, and a difference of CTE between any of the substrate, the optical-trace layers, and the conductive-trace layers is no greater than 30 ppm/° C.

According to one aspect of the present disclosure, a substrate assembly comprises a substrate, a composite-layered structure defining a conjunction plane, and one or more optical-trace layers arranged over and/or beneath the conjunction plane, wherein the optical-trace layer defines a plurality of optical traces, and a bonding layer is disposed between the substrate and the composite-layered structure.

In some embodiments, at least part of the optical traces is formed of waveguides.

In some embodiments, the waveguides are planar, strip, or ridge waveguides.

In some embodiments, a supportive-substrate layer is defined along the conjunction plane.

In some embodiments, the supportive-substrate layer comprises adhesion, polyimide, or a combination thereof.

In some embodiments, the substrate is at least 100 mm by 100 mm in planar size.

In some embodiments, the substrate is a glass substrate, a ceramic substrate, a bismaleimide triazin laminated (BT) substrate, a fiberglass-reinforced epoxy-laminated (FR4) substrate, a build-up film, a Rogers substrate, a polyimide substrate, or any combination containing any substrate mentioned above.

In some embodiments, a plurality of passages are defined in the optical-trace layers for optical communication in a perpendicular direction to the substrate, wherein the passages pass through the bonding layer, or further through the substrate.

In some embodiments, a plurality of passages are defined in the optical-trace layers for electrical connection or optical communication in a perpendicular direction to the substrate; wherein the passages pass through the bonding layer and the supportive-substrate layer, or further through the substrate.

In some embodiments, one or more optical engines are arranged on a corresponding one of the optical-trace layers, wherein some of the optical traces of the optical-trace layer extend in a first direction along the composite-layered structure, and some extend in a second direction; the first direction is non-parallel with the second direction; some of the optical engines control the optical traces in either or both of the first direction and the second direction.

In some embodiments, one or more optical engines are arranged on corresponding ones of the optical-trace layers in a respective manner, wherein some of the optical traces of one of the optical-trace layers extend in a first direction, and some of the optical traces of another optical-trace layer extend in a second direction; the first direction is non-parallel with the second direction; some of the optical engines control either or all of the input and output of the optical traces in both the first and second direction; the optical engines are provided with the corresponding optical-trace layers with optical communication.

In some embodiments, some of the optical engines control the optical traces in a perpendicular direction to the composite-layered structure.

In some embodiments, the optical engine includes one or more photoelectric conversion members and one or more optical modulators.

In some embodiments, the optical engine includes one or more optical trace steering components.

In some embodiments, the substrate and the optical-trace layers define a coefficient of thermal expansion, and a difference of CTE between any of the substrate and the optical-trace layers is no greater than 30 ppm/° C.

According to one aspect of the present disclosure, an electronic device is provided, comprising a substrate assembly as described above and a plurality of semiconductor components arranged on the composite-layered structure of the substrate assembly, wherein some of the semiconductor components electrically connect the conductive-trace layers, and some optically communicate with the optical-trace layers.

In some embodiments, one or more of the semiconductor components are SoCs (System-on-Chip) and/or HBMs (high bandwidth memory).

In some embodiments, at least some of the semiconductor components are stacked over one another.

In some embodiments, each of the semiconductor components includes a plurality of I/O pins, and a quantity of the I/O pins of one or more of the computing and memory components is no less than 300.

In some embodiments, a quantity of the I/O pins of one or more of the computing and memory components is no less than 1024.

In some embodiments, in addition to electrical connection, there is optical communication between corresponding two of the composite-layered structure, the substrate, and the semiconductor components.

According to one aspect of the present disclosure, an electronic apparatus comprises a function board, at least one substrate assembly as described above electrically connected to the function board, and a plurality of semiconductor components arranged on the composite-layered structures of the at least one substrate assembly, wherein some of the semiconductor components electrically connect the conductive-trace layers, and some optically communicate with the optical-trace layers.

In some embodiments, in addition to electrical connection, there is optical communication between corresponding two of the composite-layered structure, the substrate, the semiconductor components, and the function board.

In some embodiments, an adhesion layer is disposed between the substrate assemblies and the function board for planar attachment.

In some embodiments, some of the passages pass through the adhesion layer.

In some embodiments, the function board is further provided with a plurality of sockets for the substrate assemblies to be inserted therein in a one-on-one manner, wherein the substrate of the substrate assembly includes at least hard materials.

In some embodiments, one or more of the semiconductor components are SoCs (System-on-Chip) and/or HBMs (high bandwidth memory).

In some embodiments, at least some of the semiconductor components are stacked over one another.

In some embodiments, each of the semiconductor components includes a plurality of I/O pins, and a quantity of the I/O pins of one or more of the computing and memory components is no less than 300.

In some embodiments, a quantity of the I/O pins of one or more of the computing and memory components is no less than 1024.

According to one aspect of the present disclosure, an electronic apparatus comprises a function board, a plurality of composite-layered structures each defining a conjunction plane, one or more conductive-trace layers and one or more optical-trace layers arranged over and/or beneath the conjunction plane, wherein the optical-trace layer defines a plurality of optical traces and the conductive-trace layer defines a plurality of conductive traces, and a plurality of semiconductor components arranged on the composite-layered structures, wherein some of the semiconductor components electrically connect the conductive-trace layers, and some optically communicate with the optical-trace layers.

In some embodiments, the one or more conductive-trace layers and the one or more optical-trace layers are mixed in a coplanar manner.

In some embodiments, either of the conductive-trace layer and the optical-trace layer is over the conjunction plane, and the other is beneath the conjunction plane.

In some embodiments, in addition to electrical connection, there is optical communication between corresponding two of the composite-layered structure, the semiconductor components, and the function board.

In some embodiments, some of the conductive-trace layers construct a redistribution layer (RDL).

In some embodiments, the conductive trace defines a trace width, and at least part of the trace width is no greater than 10 μm.

In some embodiments, the conductive trace defines a trace width, and at least part of the trace width is no greater than 2 μm.

In some embodiments, a supportive-substrate layer is defined along the conjunction plane.

In some embodiments, the conductive-trace layer(s) is/are arranged over the supportive-substrate layer; the optical-trace layer(s) is/are arranged over the supportive-substrate layer; or the conductive-trace layer(s) and the optical-trace layer(s) are mixed in a coplanar manner and arranged over the supportive-substrate layer.

In some embodiments, the supportive-substrate layer comprises adhesion, polyimide, or a combination thereof.

In some embodiments, the function board is a glass substrate, a ceramic substrate, a bismaleimide triazin laminated (BT) substrate, a fiberglass-reinforced epoxy-laminated (FR4) substrate, a build-up film substrate, a Rogers substrate, a PPO substrate, or a polyimide substrate, or any combination including any substrate mentioned above.

In some embodiments, a plurality of passages are defined, which are formed in either or both of the conductive-trace layers and the optical-trace layers for electrical connection or optical communication in a perpendicular direction to the substrate, wherein the passages pass through the bonding layer or further through the substrate.

In some embodiments, a plurality of passages are defined, which are formed in either or both of the conductive-trace layers and the optical-trace layers for electrical connection or optical communication in a perpendicular direction to the substrate; wherein the passages pass through the bonding layer and the supportive-substrate layer, or further through the substrate.

In some embodiments, one or more of the semiconductor components are SoCs (System-on-Chip) and/or HBMs (high bandwidth memory).

In some embodiments, at least some of the semiconductor components are stacked over one another.

In some embodiments, each of the semiconductor components includes a plurality of I/O pins, and a quantity of the I/O pins of one or more of the computing and memory components is no less than 300.

In some embodiments, a quantity of the I/O pins of one or more of the computing and memory components is no less than 1024.

In some embodiments, one or more optical engines are arranged on a corresponding one of the optical-trace layers, wherein some of the optical traces of the optical-trace layer extend in a first direction along the composite-layered structure, and some extend in a second direction; the first direction is non-parallel with the second direction; some of the optical engines control the optical traces in either or both of the first direction and the second direction.

In some embodiments, one or more optical engines are arranged on corresponding ones of the optical-trace layers in a respective manner, wherein some of the optical traces of one of the optical-trace layers extend in a first direction, and some of the optical traces of another optical-trace layer extend in a second direction; the first direction is non-parallel with the second direction; some of the optical engines control either or all of the input and output of the optical traces in both the first and second direction; the optical engines are provided with the corresponding optical-trace layers with electrical connection or optical communication.

In some embodiments, some of the optical engines control the optical traces in a perpendicular direction to the composite-layered structure.

In some embodiments, the optical engine includes one or more photoelectric conversion members and one or more optical modulators.

In some embodiments, the optical engine includes optical trace steering component.

In some embodiments, the substrate, the optical-trace layers, and the conductive-trace layers define a coefficient of thermal expansion, and a difference of CTE between any of the substrate, the optical-trace layers, and the conductive-trace layers is no greater than 30 ppm/° C.

In some embodiments, the substrate, the optical-trace layers, the conductive-trace layers, and the supportive-substrate layer define a coefficient of thermal expansion, and a difference of CTE between any of the substrate, the optical-trace layers, and the conductive-trace layers is no greater than 30 ppm/° C.

According to one aspect of the present disclosure, a manufacturing method for an electronic apparatus is provided. The method comprises: forming a composite-layered structure on a substrate, in which the composite-layered structure defines a conjunction plane, and one or more conductive-trace layers and one or more optical-trace layers are arranged over and/or beneath the conjunction plane, wherein the optical-trace layer defines a plurality of optical traces and the conductive-trace layer defines a plurality of conductive traces; implementing either of two steps of: disposing a plurality of semiconductor components on the composite-layered structure, wherein some of the semiconductor components at least electrically connect the conductive-trace layers, and some optically communicate with the optical-trace layers; and providing a function board for stacking beneath and at least electrically connecting with the composite-layered structure; and carrying out the other one of the two steps.

In some embodiments, in the step of forming the composite-layered structure on the substrate, either of two steps is implemented: forming one or more optical-trace layers on an original board, in which the optical-trace layer includes a plurality of optical traces, and removing at least part of the original board from the optical-trace layers; or forming one or more conductive-trace layers on an original board, in which the conductive-trace layer includes a plurality of conductive traces, and removing at least part of the original board from the conductive-trace layers; and in the step of forming the composite-layered structure on the substrate, stacking the conductive-trace layers over the optical-trace layers, or stacking the optical-trace layers over the conductive-trace layers.

In some embodiments, in the step of forming the composite-layered structure on the substrate, the conductive-trace layers and the optical-trace layers are arranged in a coplanar manner.

In some embodiments, in the step of forming the composite-layered structure on the substrate, the original board includes a rigid board, and a resilient board stacked over the rigid board; the rigid board is removed from the resilient board, resulting in a composite-layered structure with the resilient board and without the rigid board.

In some embodiments, in the step of forming the composite-layered structure on the substrate, the original board is a rigid board; the composite-layered structure is removed from the rigid board, resulting in the composite-layered structure without the rigid board.

In some embodiments, in the step of forming the composite-layered structure on the substrate, an adhesion layer is further provided between the conductive-trace layers and the optical-trace layers.

In some embodiments, in the step of forming the composite-layered structure on the substrate, a supportive-substrate layer is further defined along the conjunction plane.

In some embodiments, the supportive-substrate layer includes a resilient layer or an adhesion layer, or a combination thereof.

In some embodiments, the conductive trace defines a trace width, and at least part of the trace width is no greater than 10 μm.

In some embodiments, at least part of the optical traces are formed of waveguides.

In some embodiments, the substrate is at least 100 mm by 100 mm in planar size.

In some embodiments, the substrate is a glass substrate, a ceramic substrate, a bismaleimide triazin laminated (BT) substrate, a fiberglass-reinforced epoxy-laminated (FR4) substrate, a build-up film, a Rogers substrate, a polyimide substrate, or any combination including any substrate mentioned above.

In some embodiments, the function board is a glass substrate, a ceramic substrate, a bismaleimide triazin laminated (BT) substrate, a fiberglass-reinforced epoxy-laminated (FR4) substrate, a build-up film, a Rogers substrate, a PPO substrate, a polyimide substrate, or any combination including any substrate mentioned above.

In some embodiments, in addition to electrical connection, there is optical communication between corresponding two of the composite-layered structure, the semiconductor components, and the function board.

In some embodiments, after the step of forming the composite-layered structure on the substrate, an adhesion layer is further provided between the composite-layered structure and the function board.

In some embodiments, after the step of forming the composite-layered structure on the substrate, the composite-layered structures are further connected with the function board by a plurality of sockets.

According to one aspect of the present disclosure, a manufacturing method for an electronic apparatus is provided. The method comprises: forming one or more conductive-trace layers and one or more optical-trace layers as a composite-layered structure on a function board, wherein the conductive-trace layer defines a plurality of conductive traces and the optical-trace layer defines a plurality of optical traces; and disposing a plurality of semiconductor components on the function board, wherein some of the semiconductor components electrically connect the conductive-trace layers, and some optically communicate with the optical-trace layers.

In some embodiments, in the step of forming the composite-layered structure, the conductive-trace layers and the optical-trace layers are formed in a coplanar manner.

In some embodiments, in the step of forming the composite-layered structure, the conductive-trace layers and the optical-trace layers are formed in a stacked manner.

In some embodiments, in the step of forming the composite-layered structure, either of the conductive-trace layers and the optical-trace layers is formed on the function board, and the other is then applied upon the previous one.

In some embodiments, in the step of forming the composite-layered structure on the substrate, an adhesion layer is further provided between the conductive-trace layers and the optical-trace layers.

In some embodiments, in the step of forming the composite-layered structure on the substrate, a supportive-substrate layer is further defined along the conjunction plane.

In some embodiments, the supportive-substrate layer includes a resilient layer or an adhesion layer, or a combination thereof.

In some embodiments, the conductive trace defines a trace width, and at least part of the trace width is no greater than 10 μm.

In some embodiments, at least part of the optical traces are formed of waveguides.

In some embodiments, the substrate is at least 100 mm by 100 mm in planar size.

In some embodiments, the function board is a glass substrate, a ceramic substrate, a bismaleimide triazin laminated (BT) substrate, a fiberglass-reinforced epoxy-laminated (FR4) substrate, a build-up film, a Rogers substrate, a PPO substrate, a polyimide substrate, or any combination including any substrate mentioned above.

In some embodiments, in addition to electrical connection, there is optical communication between corresponding two of the composite-layered structure, the semiconductor components, and the function board.

In some embodiments, after the step of forming the composite-layered structure on the substrate, an adhesion layer is further provided between the composite-layered structure and the function board.

### BRIEF DESCRIPTION OF THE DRAWINGS

The disclosure will become more fully understood from the detailed description and accompanying drawings, which are given for illustration only, and thus are not limitative of the present disclosure, and wherein:

FIGS. 1A to 1D are schematic diagrams showing different implementation aspects of the conductive-trace layers in the substrate assemblies of the present invention;

FIGS. 2A to 2D are schematic diagrams showing different implementation aspects of the optical-trace layers in the substrate assemblies of the present invention;

FIGS. 3A to 3D, 3′A to 3′D and 3E are schematic diagrams showing different implementation aspects of the conductive-trace layers and optical-trace layers of the substrate assemblies of the present invention having different stacking types on a single substrate;

FIGS. 4A to 4D are schematic diagrams showing that the conductive-trace layer and the optical-trace layer of the present invention are configured in a coplanar manner on a single substrate;

FIGS. 5A to 5D, 5′A to 5′D, 6A to 6D and 6′A to 6′D are schematic diagrams of the electronic apparatus of the present invention having different implementation aspects;

FIG. 7 is a schematic diagram showing that a plurality of composite-layered structures in the electronic apparatus of the present invention are directly connected to a function board and does not include a substrate and a resilient board;

FIGS. 8A to 8B is a schematic diagrams showing different implementation aspects of the semiconductor components in an electronic device configured on the composite-layered structures of the substrate assembly of the present invention;

FIGS. 9A to 9C are schematic diagrams of setting an adhesion layer between the substrate assembly and the function board of the present invention to achieve planar bonding;

FIGS. 10A to 10E, 10E1, 10E2 and 10F to 10G are schematic diagrams of different implementation forms of the optical-trace layer set on the function board of the present invention;

FIGS. 11A to 11D are schematic diagrams of the conductive-trace layer of the present invention having different process steps;

FIGS. 12A to 12D are schematic diagrams of different process steps of the optical-trace layer of the present invention;

FIGS. 13A to 13D are schematic diagrams showing different manufacturing steps of the conductive-trace layer and the optical-trace layer of the present invention configured in a coplanar manner on a single substrate; and

FIG. 14 is a schematic diagram showing that the conductive-trace layer and the optical-trace layer of the present invention are arranged on a function board in a coplanar manner.

### DETAILED DESCRIPTION OF THE DISCLOSURE

The disclosure will become more fully understood from the detailed description and accompanying drawings, which are given for illustration only, and thus are not limitative of the present disclosure.

The present disclosure will be apparent from the following detailed description, which proceeds with reference to the accompanying drawings, wherein the same references relate to the same elements.

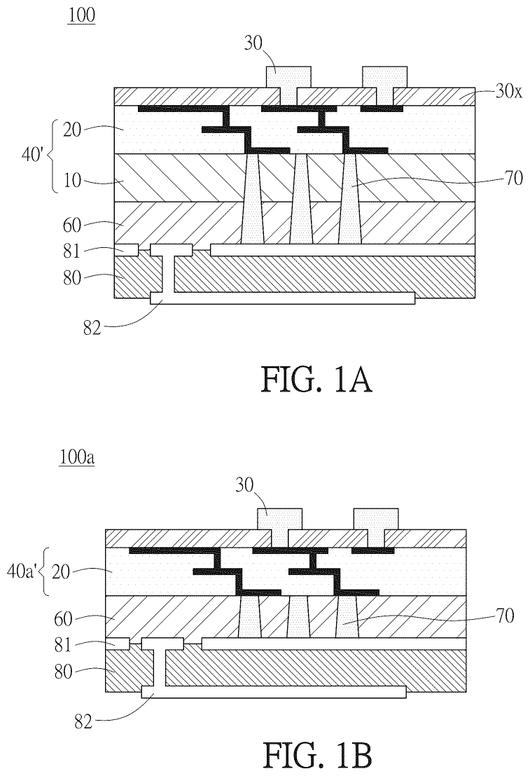

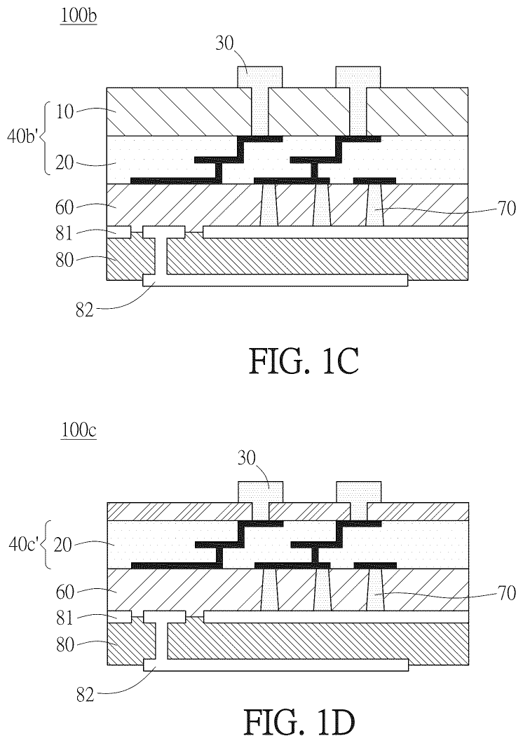

A substrate assembly illustrated as FIGS. 1A to 1D in the current disclosure is at least partial structure or manufacture method of the electronic device disclosed in the '746 provisional.

The substrate assembly 100 to 100c includes a substrate 80, a composite-layered structure (without numeral, here depicts a redistribution structure 40′ to 40c′ configured with a redistribution layer trace 20, which is indicating an RDL trace in the '746 provisional), which is electrically connected with a conductive pad 30 and a top conductive trace 30x, a bonding layer 60 (depicts an adhesion layer in the '746 provisional) attaching the redistribution structure 40′ to 40c′ to the substrate 80. For further electrical capability, here we have a plurality of passages (depicts conductors 70 in the '746 provisional) arranged at least through the adhesion layer and electrically connecting the composite-layered structure (the RDL trace of the redistribution structure) to (the substrate trace 81, 82 of) the substrate 80. The '746 provisional describes the electrical-connection types of the substrate assembly and how the substrate assembly makes, and all the information mentioned in the '746 provisional are relative to the current disclosure and can be applied to the current disclosure. It should be further noted that the top conductive trace 30x here may not be numbered in most figures.

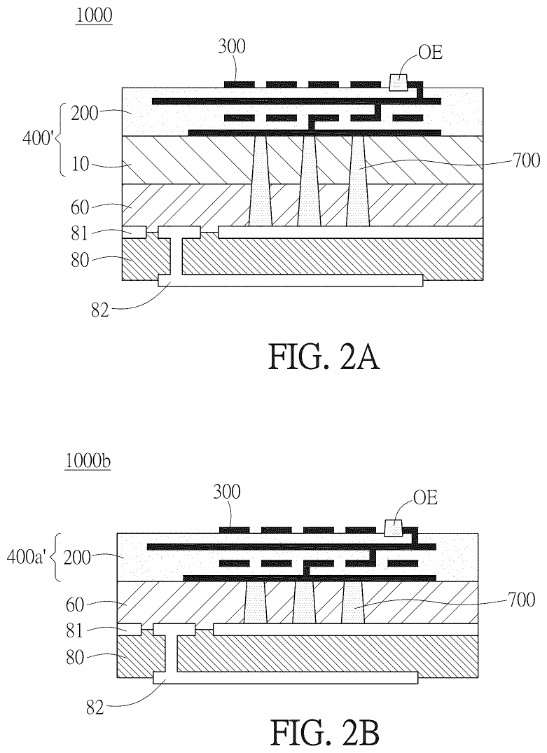

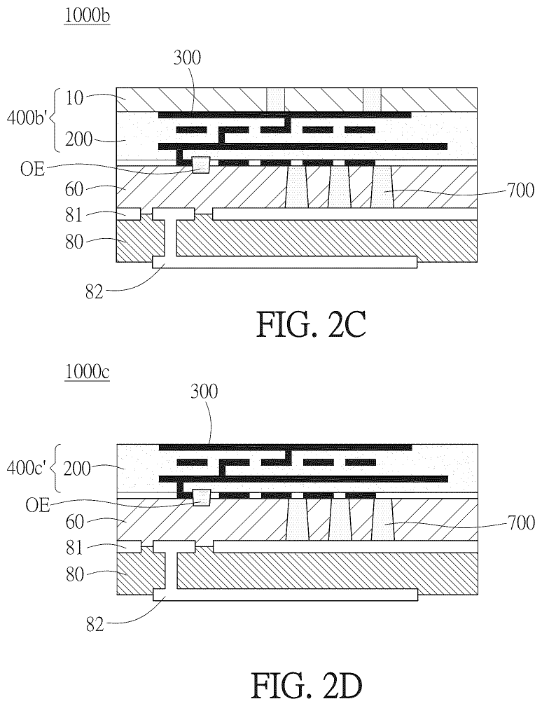

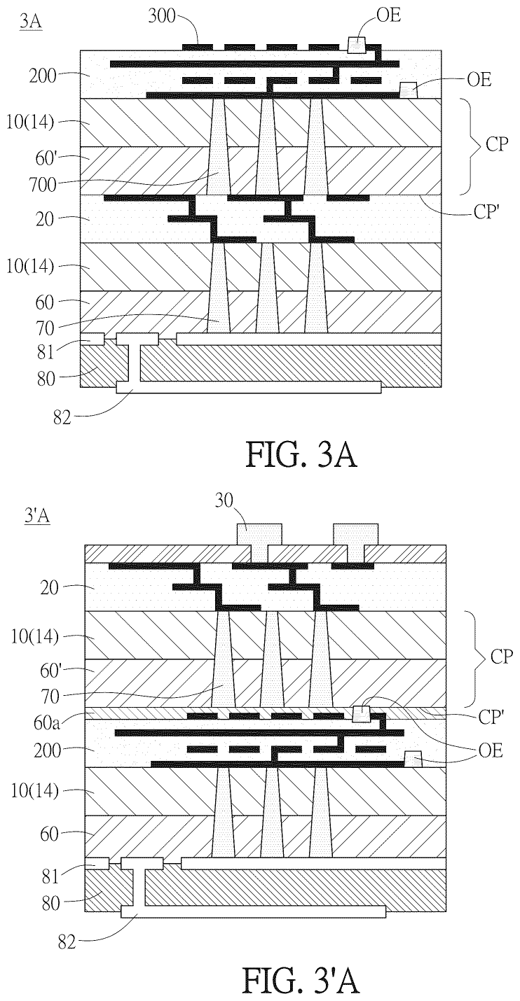

We should notice that FIGS. 1A to 1D describe some embodiments related to the conductive-trace layers part of the substrate assembly. We also may know that the conductive-trace layer of the substrate assembly can be replaced by the optical-trace layer in FIGS. 2A to 2D and may understand that all the optical-trace layer(s) may be accomplished in way of optical approaches. The substrate assembly 1000 to 1000c includes a substrate 80 with substrate traces 81, 82 arranged on opposite surfaces thereof, a composite-layered structure 400′ to 400c′ (here depicts the optical-trace layer), a bonding layer 60 (here depicts an adhesion layer as well) attaching the composite-layered structure to the substrate 80. For further optical capability, a plurality of passages 700, for at least optical communication, arranged at least through the bonding layer 60 to the substrate 80.

For clarify the construction of the substrate assembly in the current disclosure, what we emphasis is the substrate assembly including a substrate, a composite-layered structure, and a bonding layer adhesive between the substrate and the composite-layered structure. The composite-layered structure defines a conjunction plane, which may be a virtue (conceptual) plane or a physical (solid) plane, and one or more conductive-trace layers, see, for example, composite-layered structures 40′ to 40c′ in FIGS. 1A to 1D, and one or more optical-trace layers, see, for example, composite-layered structures 400′ to 400c′ in FIGS. 2A to 2D, arranged over and beneath the conjunction plane; wherein the optical-trace layer defines a plurality of optical traces, and the conductive-trace layer defines a plurality of conductive traces. The conductive-trace layer(s) and the optical-trace layer(s) can be arranged over and beneath the conjunction plane in a stacked manner or a coplanar manner. It should be noted that the terms “the conductive-trace layer” or “the optical-trace layer” as used herein may refer to either a single-layered structure or a composite (multi-layered) structure. Similarly, the terms “the conductive-trace layer(s)” or “the optical-trace layer(s)” may refer to either a single structure or a combination of multiple structures. For easy description, we use the term layers for expressing layer, layers, structure and structures.

In some scenarios, the substrate applicable to the current substrate assembly is expected to have a planar size of at least 100 mm by 100 mm. The substrate itself may include optical/conducive traces on either or both opposite surfaces, and one or more conducive vias optical for optical communication and electrical connection.

In some scenarios of the stacked manner, the conductive-trace layer(s) and the optical-trace layer(s) are stacked over, and an adhesion layer is arranged therebetween. It should be understood that the terms “bonding layer” and “adhesion layer” are used herein merely to distinguish between different components (layers), without implying any difference in their inherent properties or characteristics.

In some scenarios of the stacked manner, either or both of the conductive-trace layer(s) and the optical-trace layer(s) may be manufactured without any board. In some scenarios of the stacked manner, either or both of the conductive-trace layer(s) and the optical-trace layer(s) may be manufactured with a resilient board, and after the stack manner thereof, at least one resilient board is arranged thereon.

In some scenarios of the stacked manner, there may be two substrates in the current embodiments, both of the conductive-trace layer(s) with substrate and the optical-trace layer(s) with substrate may be stacked over with each other. Relevant embodiments will be described in detail below.

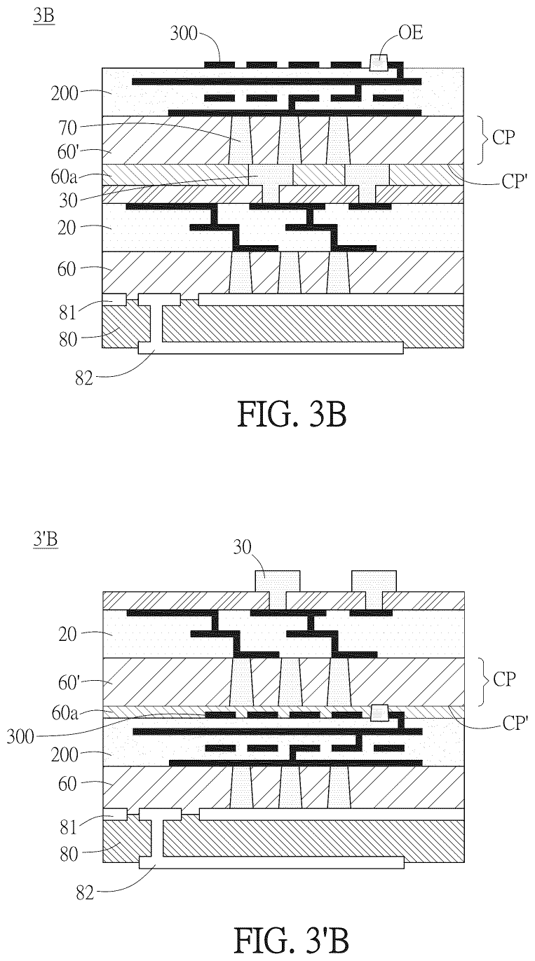

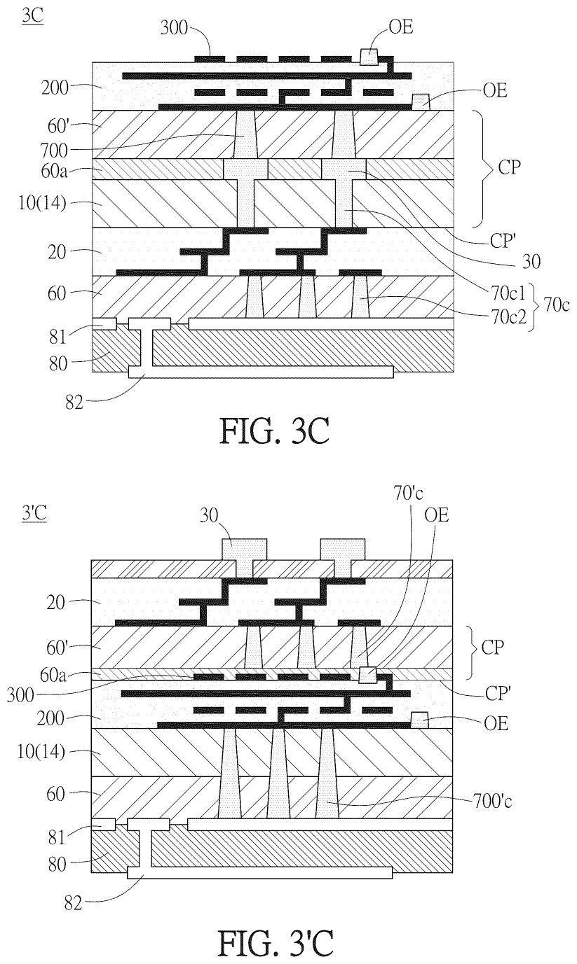

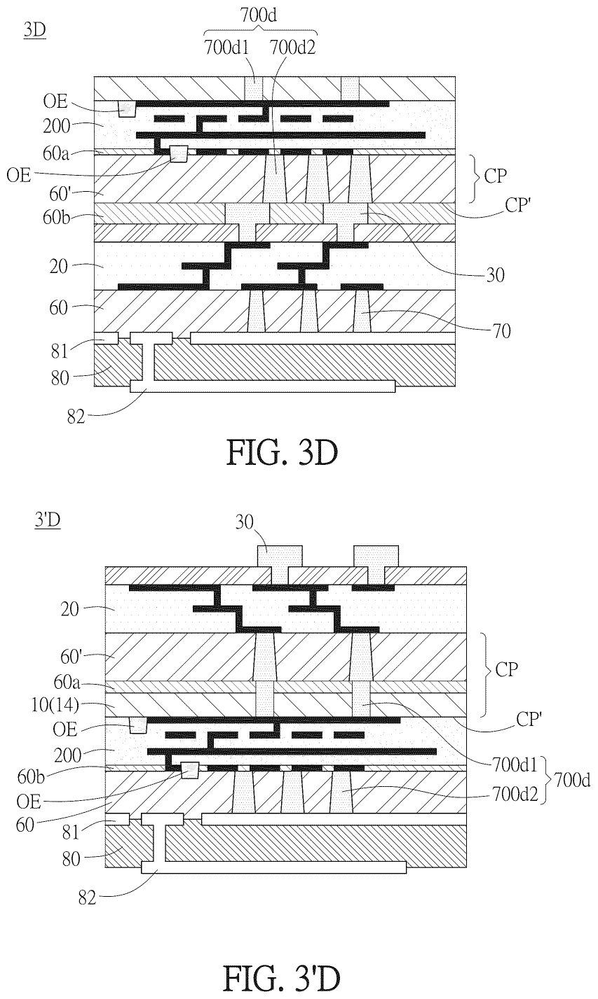

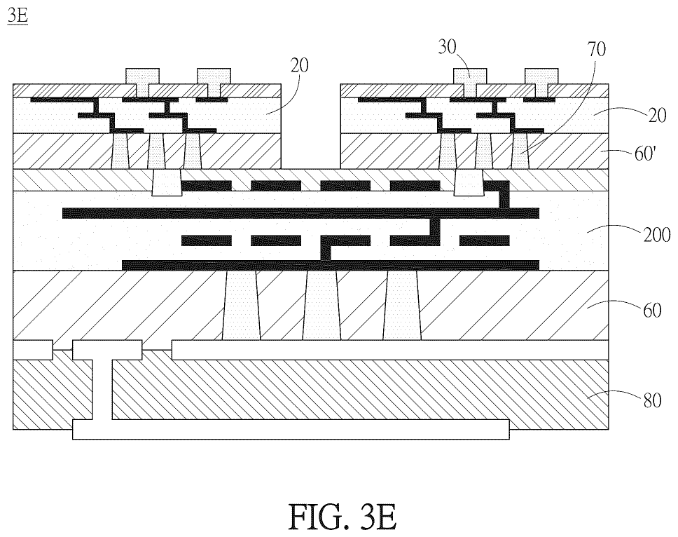

In some scenarios of the stacked manner, there may be only single substrate in these embodiments, and either or both of the conductive-trace layer(s) and the optical-trace layer(s) may be stacked over with the single substrate, see FIGS. 3A to 3′D showing some (not all) arrangements and combination thereof. A substrate assembly includes a substrate 80, a composite-layered structure with a conjunction plane CP defined therein, and a bonding layer 60 between the substrate 80 and the composite-layered structure. The composite-layered structure including one or more optical-trace layers 200, one or more conductive-trace layers 20 stacked beneath or over the optical-trace layers 200, and the conjunction plane CP defined between the conductive-trace layers 20 and the optical-trace layers 200. Between similar drawing, we can check the comparison between which layer is stacked over the other one, and which layer is with the resilient board or not.

FIG. 3A discloses a substrate assembly 3A including a substrate 80 with traces 81, 82 on either or both surfaces thereof, a composite-layered structure with a conjunction plane CP defined therein, and a bonding layer 60 adhesive between the substrate 80 and the composite-layered structure. The composite-layered structure includes a sub optical structure including one or more optical-trace layers 200 configured with a resilient board 14 for supporting, and multiple optical engines OE, including but not limited to optical switches, photoelectric converters, optical redirectors and other optical-trace structures, capable of bidirectional photoelectric delivery, bidirectional conversion and used for optical communication, and multiple passages 700 which are formed continuously through the resilient board 14 and an adhesion layer 60′ and at least optically communicating the optical-trace layers 200 in a direction perpendicular to the substrate 80. The optical engine OE includes, but is not limited to, optical structures such as optical switches, photoelectric converters, optical deflectors, and the like. It further includes a sub conductive structure stacked beneath the sub optical structure and including one or more conductive-trace layers 20 configured with a resilient board 14 for supporting and multiple conductors 70 at least electrical connecting the conductive-trace layers 20 in a direction perpendicular to the substrate 80. An adhesion layer 60′ is arranged between the sub optical structure and sub conductive structure for combine the two individual components together. Here, a conductive pad, electrically connected to the conductive-trace layers 20, is numbered as 30 and an optical interface, optically communicated with the optical-trace layer 200, is numbered as 300. The optical interface is at least optically linked to the optical engines OE, and the passages 700 may deliver either or both of electrical connection and optically communicating between the optical-trace layers 200 and the conductive-trace layers 20, and the conductors 70 are for at least electrical connection the conductive-trace layers 20 with the substrate 80. The virtue (conceptual) conjunction plane CP is still defined between the conductive-trace layers 20 and the optical-trace layers 200, while the physical (solid) conjunction plane CP′ is defined between the adhesion layer 60′ and the conductive-trace layers 20. It is understood that multiple optical engines (not shown) can also be provided between the sub optical structure and the sub conductive structure, serving as photoelectric bidirectional converters; these optical engines can be disposed on the sub optical structure and/or the sub conductive structure; this arrangement may be applied to all embodiments disclosed herein.

FIG. 3′A discloses a substrate assembly 3′A with a different stacking way compared with the substrate assembly 3′A. In the substrate assembly 3′A, a sub conductive structure in the substrate assembly 3′A is stacked over the sub optical structure. The virtue (conceptual) conjunction plane CP is still defined between the conductive-trace layers 20 and the optical-trace layers 200, while the physical (solid) conjunction plane CP′ is defined between the adhesion layer 60′ and the optical-trace layers 200. It is noteworthy that, in this example, a planar layer 60a (which may also possess adhesive properties) may be further included between the optical-trace layers 200 and the conductive-trace layers 20, allowing the electrical signals deliver to the optical engine OE. In some of other embodiments or figures, the illustration of the planar layer 60a may be omitted. In this context, the planar layer 60a and the adhesion layer 60′ may be integrated as a single adhesive layer.

FIG. 3B discloses a substrate assembly 3B with a different incorporation way compared with the substrate assembly 3A. In the substrate assembly 3B, a sub conductive structure without the resilient board 14 is stacked beneath a sub optical structure without the resilient board 14. The virtue (conceptual) conjunction plane CP is still defined between the conductive-trace layers 20 and the optical-trace layers 200, while the physical (solid) conjunction plane CP′ is defined between the adhesion layer 60′ and the optical-trace layers 200. It is noteworthy that, in this example, the conductive pad 30 is illustrated and labeled. In this case, a planar layer 60a (which may also possess adhesive properties) may be further included between the optical-trace layers 200 and the conductive-trace layers 20, allowing the conductive pad 30 to be electrically connected to the conductor 70. In some of other embodiments or figures, the illustration of the conductive pad 30 and the planar layer 60a may be omitted.

FIG. 3′B discloses a substrate assembly 3′B with a different stacking way compared with the substrate assembly 3B. In substrate assembly 3′B, a sub conductive structure without the resilient board 14 is stacked over a sub optical structure without the resilient board 14.

FIG. 3C discloses a substrate assembly 3C with a different incorporation way compared with the substrate assembly 3A. In the substrate assembly 3C, a sub conductive structure with the resilient board 14 is stacked beneath a sub optical structure without the resilient board 14, and the resilient board 14 of the sub conductive structure faces the sub optical structure. Furthermore, we can see FIG. 3A, the passages 700 are formed through the resilient board 14 and the adhesion layer 60′ consistently as well, the conductors 70 are formed through the resilient board 14 and the bonding layer 60 consistently as well. However, in the substrate assembly 3C, the passages 700c are formed through the adhesion layer 60′ only, multiple conductors 70c are divided into two sets, one set conductors 70c1 is penetrating through the resilient board 14 for either or both of the optical communication/electrical connection with the optical-trace layers 200, and the other set conductors 70c2 is penetrating through the bonding layer 60 for the electrical connection with the substrate 80. It is understood that the stacking manner maybe upside down in another embodiment, for example, a sub conductive structure with the resilient board 14 is stacked over a sub optical structure without the resilient board 14, and the resilient board 14 of the sub conductive structure may face outwardly.

FIG. 3′C discloses a substrate assembly 3′C with a different incorporation and stacking way compared with the substrate assembly 3A. In the substrate assembly 3C, a sub conductive structure without the resilient board 14 is stacked over a sub optical structure with the resilient board 14, and the resilient board 14 of the sub conductive structure faces the substrate 80. In the substrate assembly 3′C, multiple passages 700′c are formed through the resilient board 14 and the adhesion layer 60 for either or both of the optical communication and the electrical connection, multiple conductors 70′c are formed through the bonding layer 60′ for the electrical connection with the sub optical structure.

It is understood that the stacking manner maybe upside down in another embodiment, for example, a sub conductive structure without the resilient board 14 is stacked beneath a sub optical structure with the resilient board 14, and the resilient board 14 of the sub optical structure may face outwardly. As illustrated in FIG. 3D, which discloses a substrate assembly 3D with a different incorporation and stacking way compared with the substrate assembly 3′C. A planar layer 60a may be further provided between the bonding layer 60 and the optical-trace layers 200; in some embodiments, the planar layer 60a and the adhesion layer 60′ may also be integrated as a single adhesive layer. In the substrate assembly 3D, the conductors 70 are formed through the bonding layer 60 only, multiple passages 700d are divided into two sets, one set passages 700d1 is penetrating through the resilient board 14 for either or both of the optical communication/electrical connection with the optical-trace layers 200, and the other set passages 700d2 is penetrating through the adhesion layer 60′ for the electrical connection with the conductive-trace layer 20.

FIG. 3′D discloses a substrate assembly 3′D with a different incorporation and stacking way compared with the substrate assembly 3′C. A sub conductive structure without the resilient board 14 is stacked over a sub optical structure with the resilient board 14, and the resilient board 14 of the sub optical structure may face the sub conductive structure. The conductors 70 are formed through the adhesion layer 60′ only, multiple passages 700d are divided into two sets, one set passages 700d1 is penetrating through the resilient board 14 for either or both of the optical communication/electrical connection with the optical-trace layers 200, and the other set passages 700d2 is penetrating through the bonding layer 60 for the electrical connection with the substrate 80.

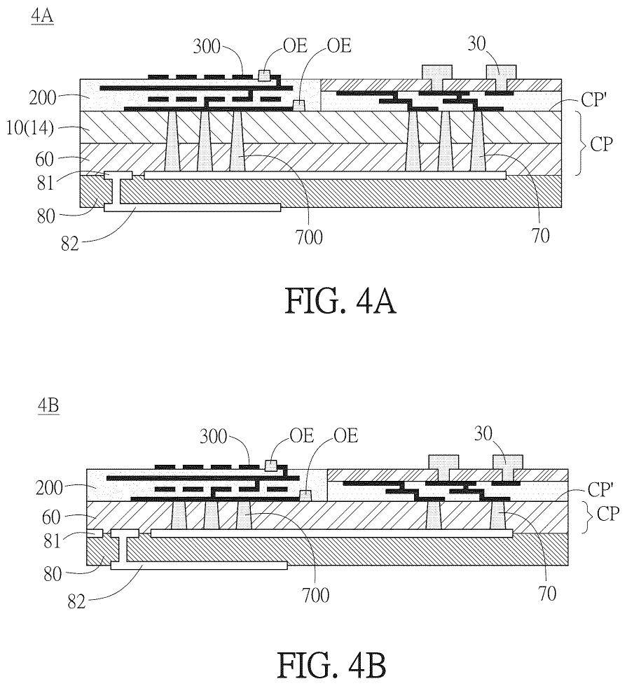

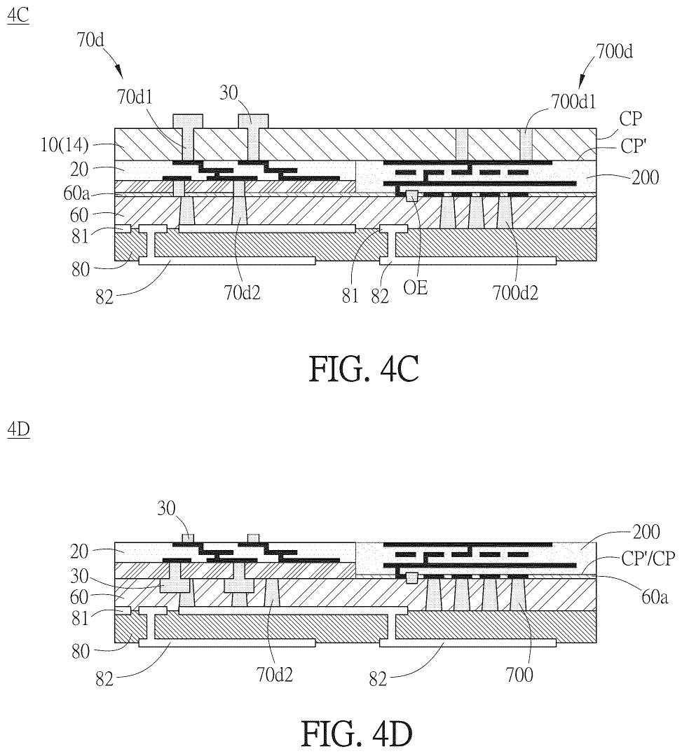

In some scenarios of the coplanar manner, the conductive-trace layer(s) and the optical-trace layer(s) are coplanar-arranged on a single substrate, illustrated in FIGS. 4A to 4D. A substrate assembly includes a substrate 80, a composite-layered structure, a bonding layer 60 between the substrate 80 and the composite-layered structure, and a conjunction plane CP is defined between the composite-layered structure and the substrate 80. The composite-layered structure including one or more optical-trace layers 200 and one or more conductive-trace layers 20 in a coplanar way. Between similar drawing, we can check the comparison between which layer is stacked over the other one, and which layer is with the resilient board or not.

FIG. 4A discloses a substrate assembly 4A including a substrate 80 with traces 81, 82 on either or both surfaces thereof, a composite-layered structure, a bonding layer 60 between the substrate 80 and the composite-layered structure, and a conjunction plane CP is defined between the composite-layered structure and the substrate 80. The optical-trace layers 200 of a sub optical structure and the conductive-trace layer 20 of a sub conductive structure may be arranged in a divided, mixed, staggered, continual or discontinue manner. The sub optical structure and the sub conductive structure may share the same or different resilient board 14, and they share in this embodiment. The bonding layer 60 connects the substrate 80 and the composite-layered structure through the resilient board 14. The virtue (conceptual) conjunction plane CP is still defined between the conductive-trace layers 20 and the optical-trace layers 200, while the physical (solid) conjunction plane CP′ is together defined by the sub optical structure and the sub conductive structure facing the substrate 80. The passages 700 and conductors 70 penetrate the bonding layer 60 and the resilient board 14.

FIG. 4B discloses a substrate assembly 4B with a different stacking way compared with the substrate assembly 4A. In the substrate assembly 4B, the sub optical structure and the sub conductive structure are formed without the resilient board 14. The passages 700 and conductors 70 penetrate the bonding layer 60.

FIG. 4C discloses a substrate assembly 4B with a different stacking way compared with the substrate assembly 4A. In the substrate assembly 4C, the sub optical structure and the sub conductive structure are formed with the resilient board 14, and the resilient board 14 is remote from the substrate 80. The conductors 70d are divided into two sets, one set conductors 70d1 is penetrating through the resilient board 14 for the electrical connection with the conductive-trace layers 20, and the other set conductors 70d2 is penetrating through the bonding layer 60 for the electrical connection with the substrate 80. The passages 700d may be divided into two sets, one set passages 700d1 is penetrating through the resilient board 14 for the optical communication with the optical-trace layers 200, and the other set passages 700d2, which may be optically penetrating through the bonding layer 60 for the optical communication with the substrate 80. It should be noted that the substrate traces 81, 82 of the substrate 80 may be provided in two sets, each corresponding respectively to the conductive-trace layers 20 and the optical-trace layers 200.

FIG. 4D discloses a substrate assembly 4D with a different stacking way compared with the substrate assembly 4C. In the substrate assembly 4D, the sub optical structure and the sub conductive structure are formed without the resilient board 14. The passages 700 and conductors 70 penetrate the bonding layer 60. It should be noted that the substrate traces 82 of the substrate 80 may be provided in two sets.

In the embodiment of the coplanar structure without the resilient board, a molding layer may be applied on the top of the whole of the coplanar structure to facilitate handling. In one embodiment, the conductive-trace layer(s) and the optical-trace layer(s) may be formed individually and then arranged on one substrate/board/carrier to stack together; in another embodiment, the conductive-trace layer(s) and the optical-trace layer(s) are formed on one substrate/board/carrier in the same manufacture process; in which no absolute boundary between the conductive-trace layer(s) and the optical-trace layer(s) but interactive to each other in a mixed manner.

Returning to the detailed description of the substrate assembly, to clarify the definition of the conjunction plane, please refer to FIG. 3A, FIG. 3′A, FIG. 4A and FIG. 4′A, is a virtual plane per se. Please see where the arrow points out, the conductive-trace layer(s) and the optical-trace layer(s) depend on is defined as the conjunction plane. When there is no resilient board or adhesion layer, the conjunction plane is as the virtual plane; when there is resilient board or adhesion layer or the like, the conjunction plane becomes more physical and is defined by the bonding layer 60, the resilient board 14, or the combination thereof; wherein the conjunction plane in this embodiment may have a thickness, which do not irritate the definition thereof. In FIG. 3A to FIG. 3′D, the conjunction plane is set between the conductive-trace layer(s) and the optical-trace layer(s). In FIGS. 4A to 4D, the conjunction plane is set as the virtual plane on which the conductive-trace layer(s) and the optical-trace layer(s) are arranged.

In any embodiment of the conductive-trace layers, the conductive trace defines a trace width; at least part of the trace width is no greater than 10 μm, 5 μm or 2 μm. In any embodiment of the conductive-trace layers, the conductive trace defines a trace space; at least part of the trace space is no greater than 10 μm, 5 μm or 2 μm.

In any embodiment of the optical layers, at least part of the optical traces is formed of waveguides, which may be planar, strip or ridge. Optical fibers are also optionally adapted.

For the embodiment of the resilient board 14 or/and bonding layer 60, the elements, such as the resilient board 14 or/and bonding layer 60, other than the composite-layered structure, is defined as a supportive-substrate layer. The supportive-substrate layer is defined along the conjunction plane. In some embodiments, materials of the supportive-substrate layer includes adhesion, polyimide, or a combination thereof.

In any embodiment in the current disclosure, the substrate 80 may be a glass substrate, a ceramic substrate, a bismaleimide triazin laminated (BT) substrate, a fiberglass-reinforced epoxy-laminated (FR4) substrate, a build-up film (, such as an ajinomoto build-up film, ABF) substrate, or a Rogers substrate, a polyimide substrate, or any combination containing any substrate mentioned-above.

In any embodiment of in the current disclosure, the passages may be formed of either or both of the conductive-trace layers and the optical-trace layers for electrical connection or optical communication in a perpendicular direction for further reaching the substrate, wherein the passages may pass through any layer and material before the substrate.

Please see the OE numerals in FIGS. 3A to 3′D and 4A to 4′D. In any embodiment of in the current disclosure, the substrate assembly further includes one or more optical engines OE arranged on a corresponding one of optical-trace layers, which is reasonably on top to bottom one of the trace layers. The optical engine OE is a physical unit which is packaged, or a virtual unit which is treated as a unit unpackaged.

In any embodiment of in the current disclosure, the optical engine OE may include one or more photoelectric conversion members and one or more optical modulator, which are for input/output electrical-optical conversion. The photoelectric conversion member works with the semiconductor components, the conductive-trace layers, and may be an electrical-to-optical component, such as a laser diode; or an optical-to-electrical component, such as a photo sensor. The optical signal may be delivered by an exterior source, such as optical fiber, or an interior source, such as the laser diode. In any embodiment of in the current disclosure, the optical engine OE may include optical trace steering component, which are of adjusting the direction of the optical trace, such as the optical trace from a first waveguide to a second waveguide. In any embodiment of in the current disclosure, the optical engine OE may include the combination of the photoelectric conversion members and one or more optical modulator thereby, and the optical trace steering component.

In any embodiment in the current disclosure, the board, substrate, layers materials, each defines a coefficient of thermal expansion; and a difference of CTE between a corresponding two of them is no greater than 30 ppm/° C.

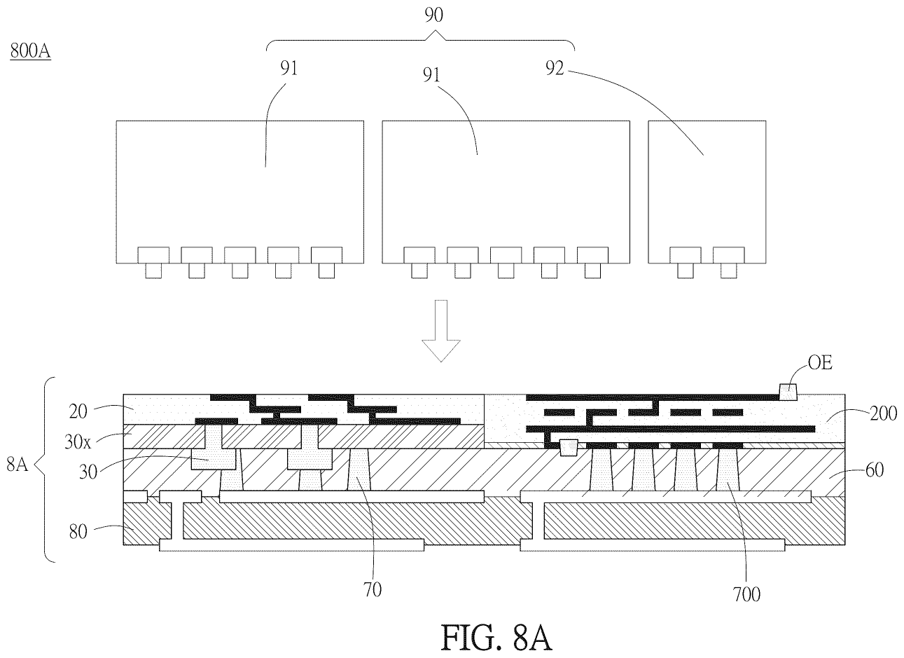

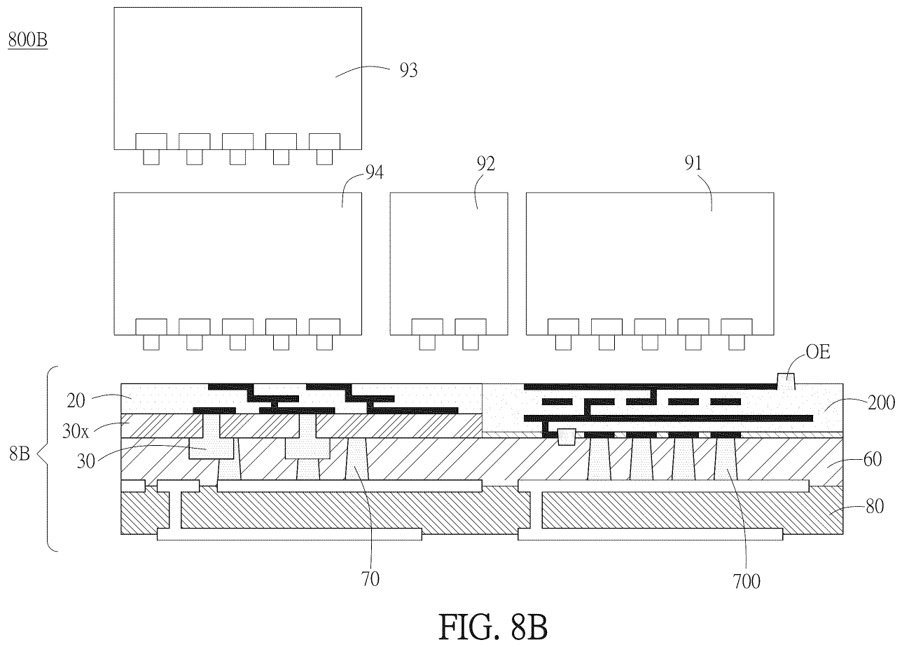

Furthermore, an electronic device in the current disclosure is any embodiment and combination mentioned above for further applied with semiconductor components thereon in which at least partial structure or manufacture method of the electronic device disclosed in the '109 provisional. Here we have the electronic device 800A, illustrated in FIG. 8A, including a substrate assembly 8A, a plurality of semiconductor components 90 arranged on the composite-layered structure configured with the optical-trace layers 200 and the conductive-trace layers 20 of the substrate assemblies 8A; wherein some of the semiconductor components 90 electrically connect the conductive-trace layers 20, and some of the semiconductor components 90 optically communicate with the optical-trace layers 200. In some embodiments, referring an electronic device 800B, at least some of the semiconductor components 90 are stacked over one another upon a substrate assemblies 8B, referred in FIG. 8B. In some embodiments, one or ones of the semiconductor components are SoCs (System-on-Chip) 91, or/and HBMs (high bandwidth memory) 92. In some embodiments, some of the semiconductor components are stacked over one another, such as a sub semiconductor component 93 stacked over another sub semiconductor component 94 optionally electrical connection with the conductive-trace layers 20 or optical communication with the optical-trace layers 200.

In some embodiments, optical-electrical communication between the conductive-trace layer 20 and the optical-trace layer 200 may adopt a many-to-many or many-to-one structural design. For example, as shown in FIG. 3E, multiple conductive-trace layers 20 can correspond to the same optical-trace layer 200, enabling multiple electronic signal channels to converge into one or a few optical channels. This design enhances signal integration and fully leverages the high bandwidth characteristics of optical communication. Such a many-to-one structure helps to simplify the configuration of the optical distribution layer, reduce process complexity, and facilitate the fabrication of high-density integrated optoelectronic hybrid substrates, making it suitable for high-performance computing and semiconductor devices with high bandwidth requirements.

In some embodiments, when bonding the conductive-trace layer (including multiple conductive traces) with the optical-trace layer (including multiple optical traces), the alignment accuracy required between the conductive-trace layer and the optical-trace layer is significantly higher than that between the conductive-trace layer and the function board. For example, the alignment accuracy between the conductive-trace layer and the optical-trace layer may be within ±1 μm, while the alignment between the conductive-trace layer and the function board may be within ±5 μm. Since optical communication structures are extremely sensitive to path alignment errors, even minor deviations can affect the coupling efficiency and transmission quality of optical signals. Therefore, the bonding process between the conductive-trace layer and the optical-trace layer requires high-precision manufacturing and inspection methods to ensure efficient integration of electronic and optical paths as well as system stability.

In any embodiment in the current disclosure, the resilient board 14 may be a build-up film (, such as an ajinomoto build-up film, ABF) substrate, or a polyimide substrate, or any combination containing any resilient board mentioned-above. In embodiment where the optical-trace layer(s) are configured with the resilient board 14, the resilient board 14 defines a thickness no greater than 50 μm.

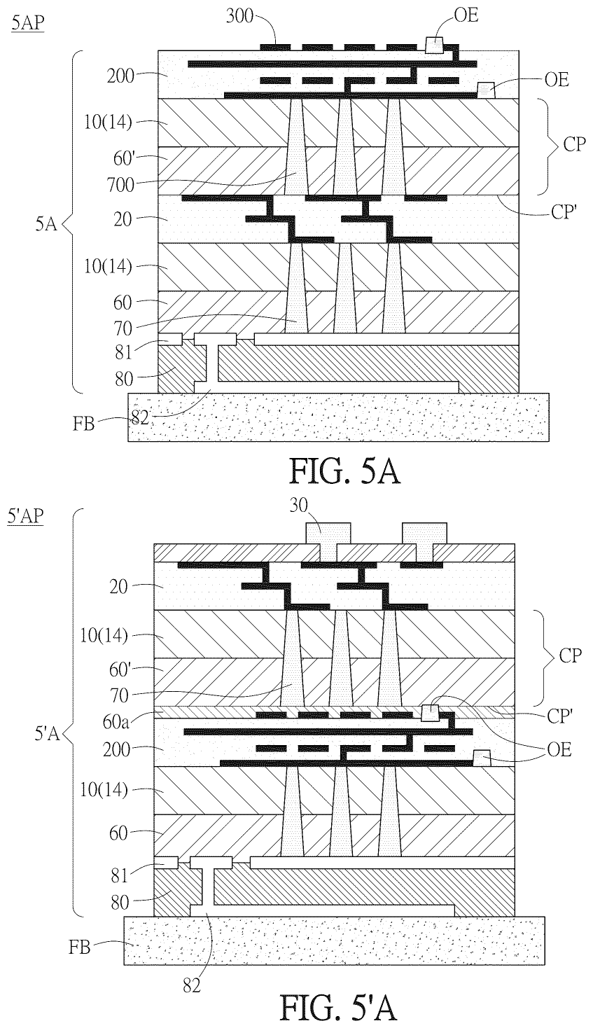

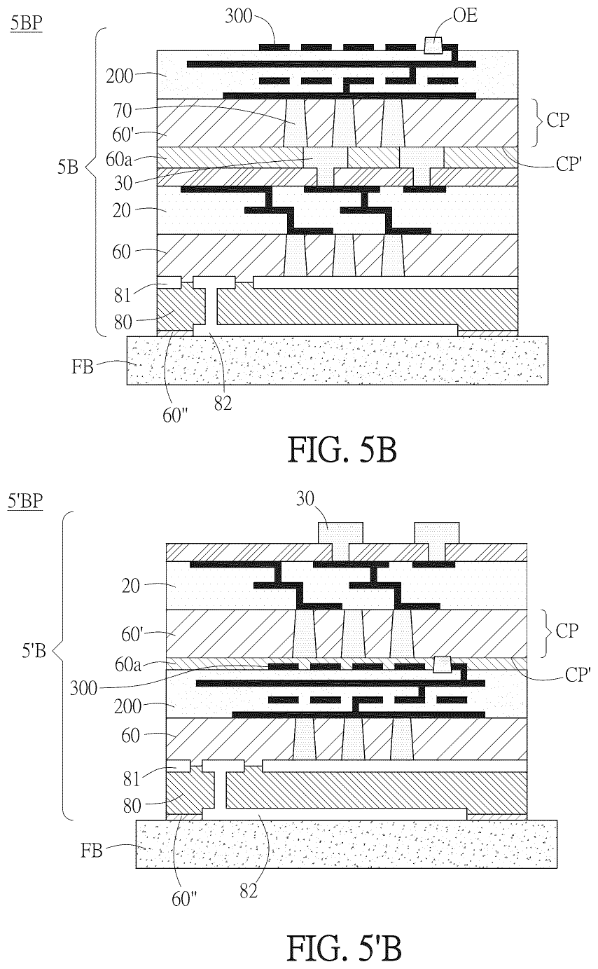

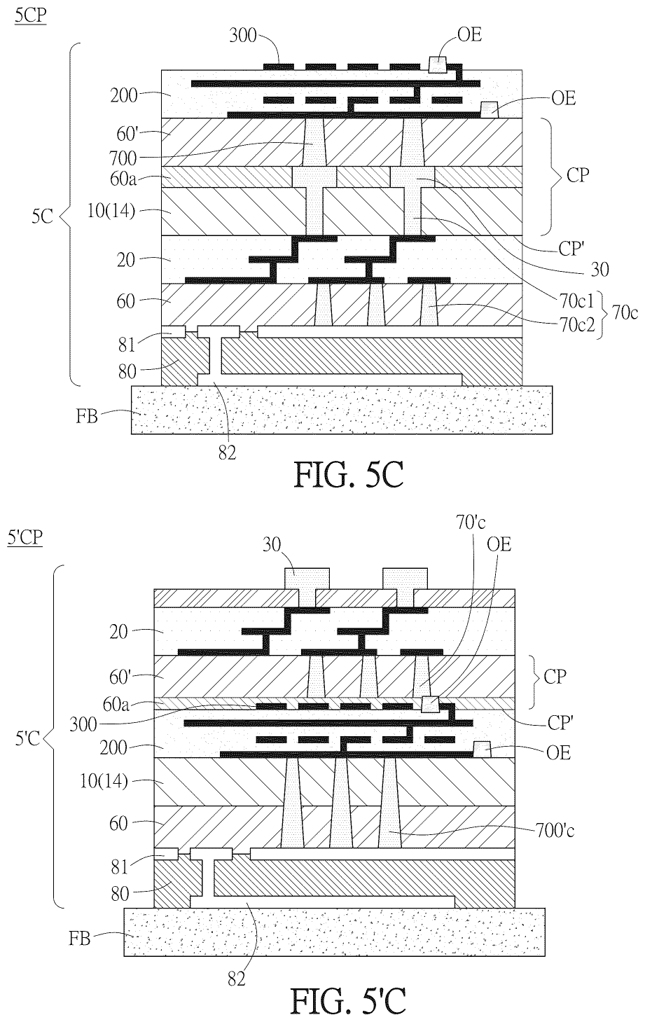

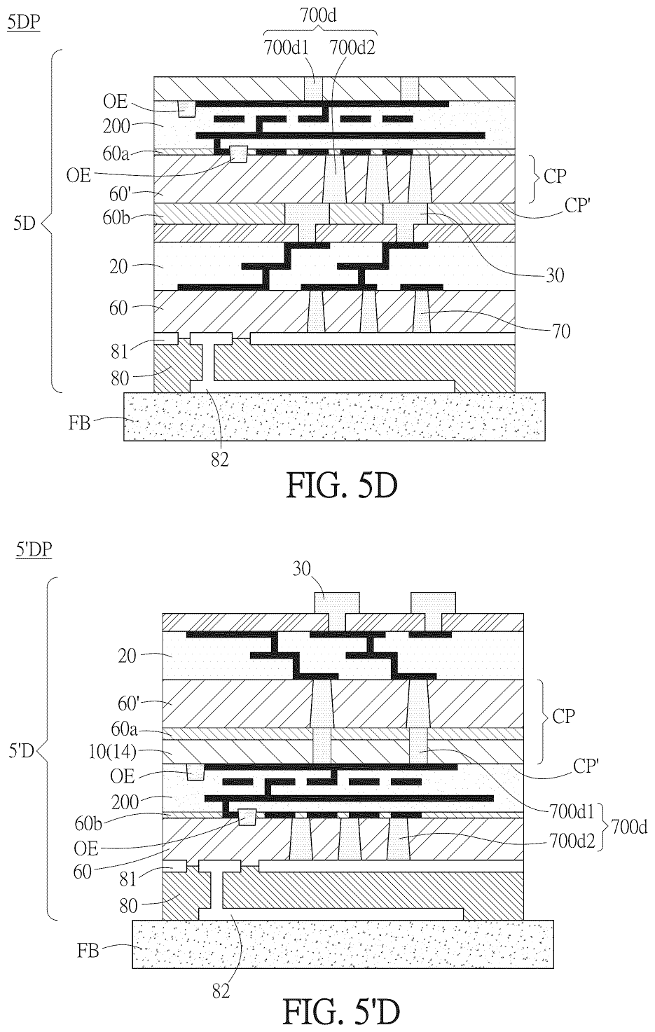

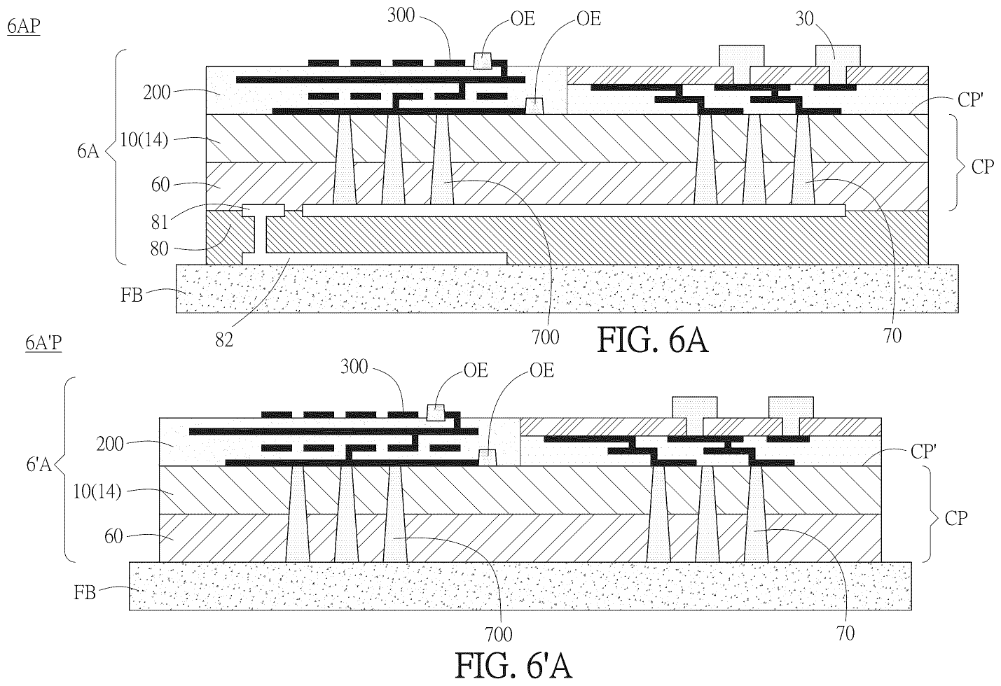

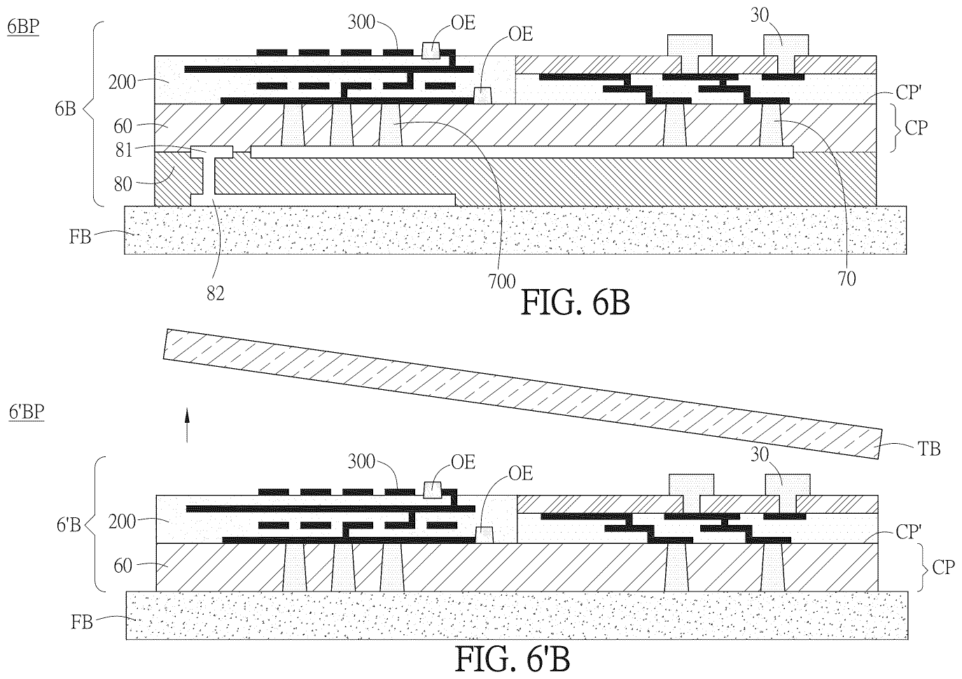

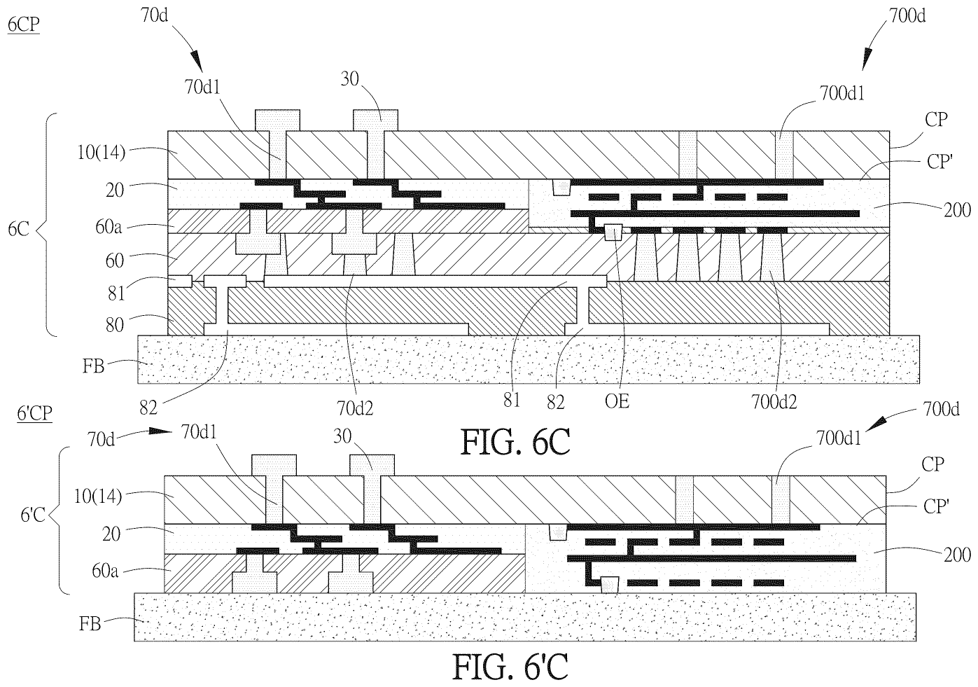

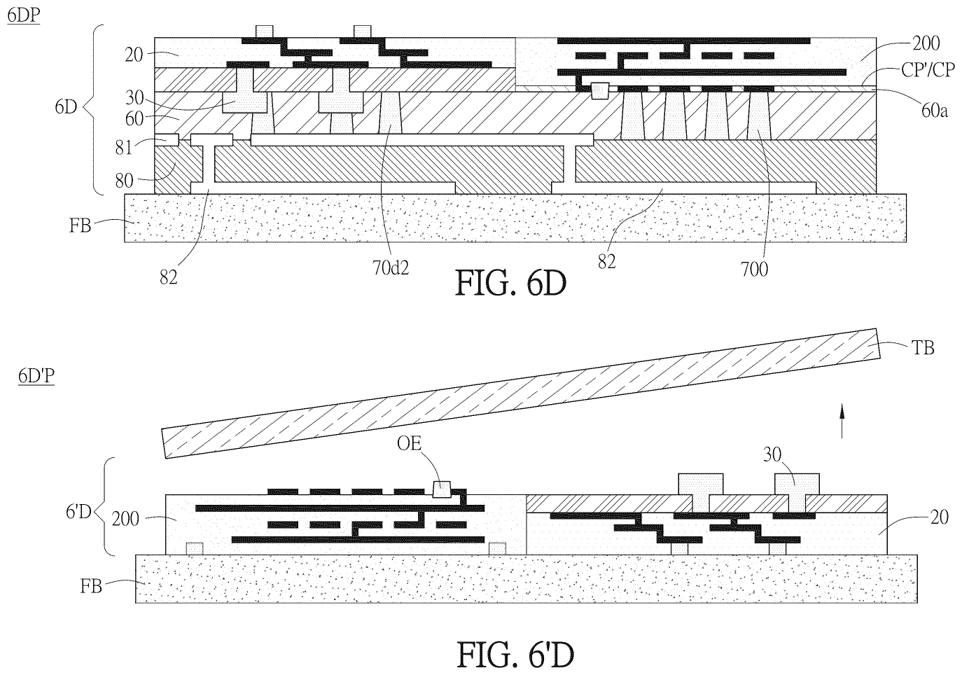

One embodiment of an electronic apparatus illustrated in FIGS. 5A to 6′D, showing the substrate assembly with the function board but without the semiconductor components, in which at least partial structure or manufacture method of the electronic device disclosed in the '109 provisional, and the whole structure is arranged on the function board. To remind the embodiment of molding layer in the '109 provisional, the molding layer may be lifted off after the substrate assembly applying on the function board, and the embodiment of the semiconductor components in the '109 provisional may be arranged before or after the substrate assembly applying on the function board. FIGS. 5A to 5′D are more drawings for further comprehension of multiple electronic apparatus 5AP to 5′DP, please noted that they are the substrate assemblies 3A to 3′D in FIGS. 3A to 3′D further arranged on a function board FB, which means the substrate 80 at least electrically connects the function board FB. The function board FB may be a motherboard, which may be a printed circuit board, or another type of substrate similar to the substrate 80, for example, a glass substrate, a ceramic substrate, a bismaleimide triazin laminated (BT) substrate, a fiberglass-reinforced epoxy-laminated (FR4) substrate, a build-up film (, such as an ajinomoto build-up film, ABF) substrate, or a Rogers substrate, a polyimide substrate, or any combination containing any substrate mentioned-above. In FIGS, 5B and 5B′, an adhesion layer 60″ may be further illustrated and applied between the substrate assemblies and the function board FB to provide planar attachment.

Multiple electronic apparatus 6AP to 6DP in FIGS. 6A to 6D are more drawings showing the substrate assemblies 4A to 4D in FIGS. 4A to 4D further arranged on a function board FB. Multiple electronic apparatus 6′AP to 6′DP in FIGS. 6′A to 6′D discloses the substrate assemblies 4′A to 4′D without the substrate 80. In FIGS. 6′B and 6′D, where the resilient board 14 is originally absent, the substrate assemblies 4′A to 4′D require an auxiliary component, such as a temporary bonding carrier TB to serve as a support during the manufacturing process.

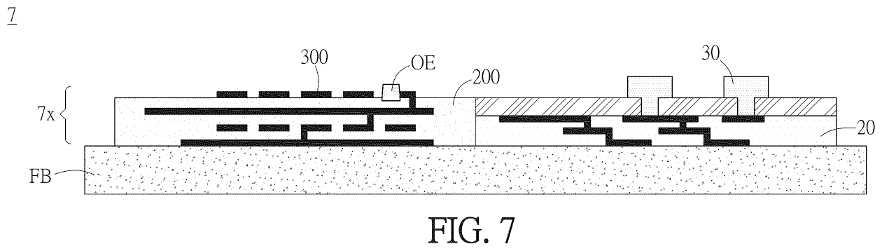

There are other embodiments of the electronic apparatus. For example, a plurality of composite-layered structures 7x, including the optical-trace layers 200 of a sub optical structure and the conductive-trace layer 20 of a sub conductive structure, are directly connected to the function board, without the substrate 80 and the resilient board 14. As shown in FIG. 7, the composite-layered structures 7x are attached to the function board FB either by direct bonding or via an additional adhesion layer. The embodiments of the composite-layered structures 7x is intended to represent various combinations of the aforementioned embodiments, and, for illustration, the conductive-trace layer and optical-trace layer are depicted in a coplanar arrangement. It should be noted that neither the bonding layer nor the adhesion layer is specifically illustrated in this embodiment, and the bonding layer or the adhesion layer may be formed directly between the composite-layered structure and the function board FB by high-pressure bonding (or further in combination with high-temperature conditionally). These various combinations are highly similar to the description motioned above, except the substrate part. To be noted, the optical-trace layers 200 of the sub optical structure and the conductive-trace layer 20 of the sub conductive structure may be arranged independently or integratively, for example, in a divided, mixed, staggered, continual or discontinue manner, and it should be further noted that the drawing here do not illustrate the semiconductor components.

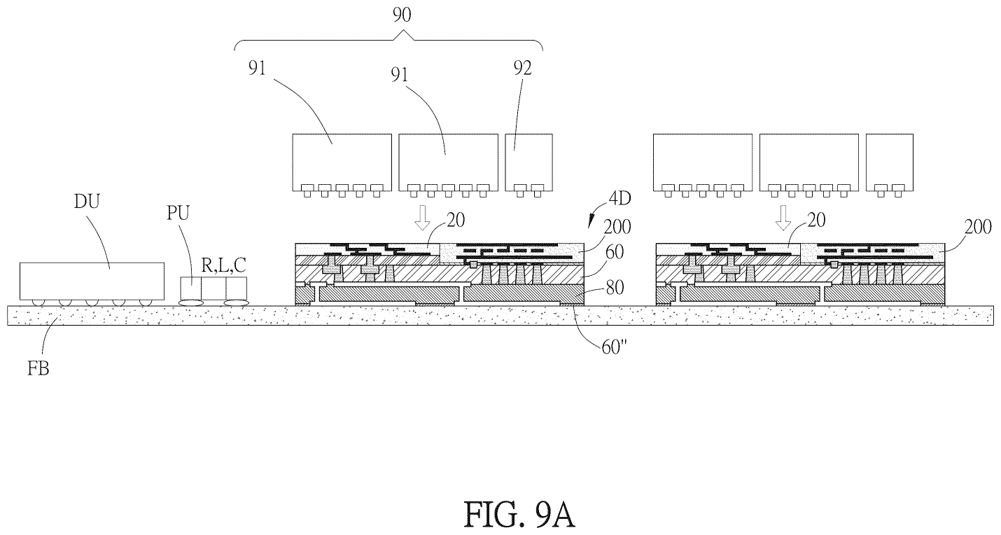

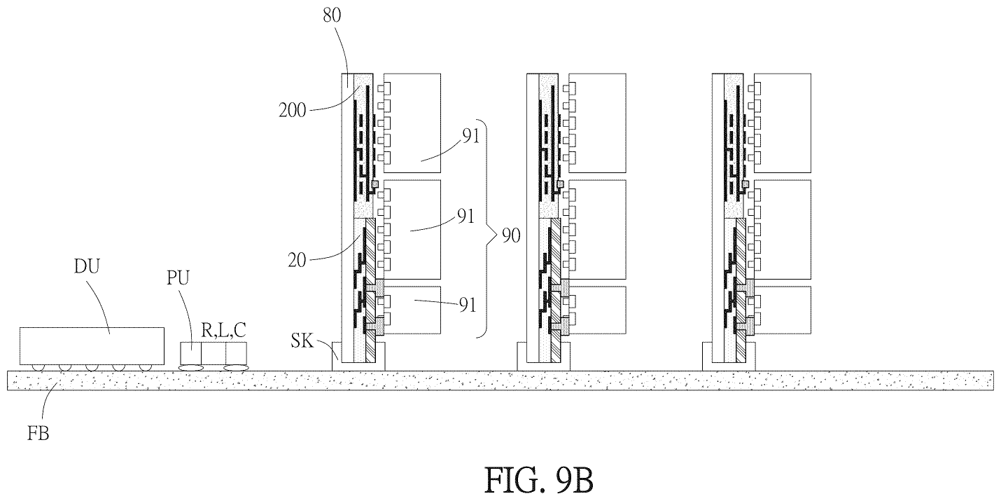

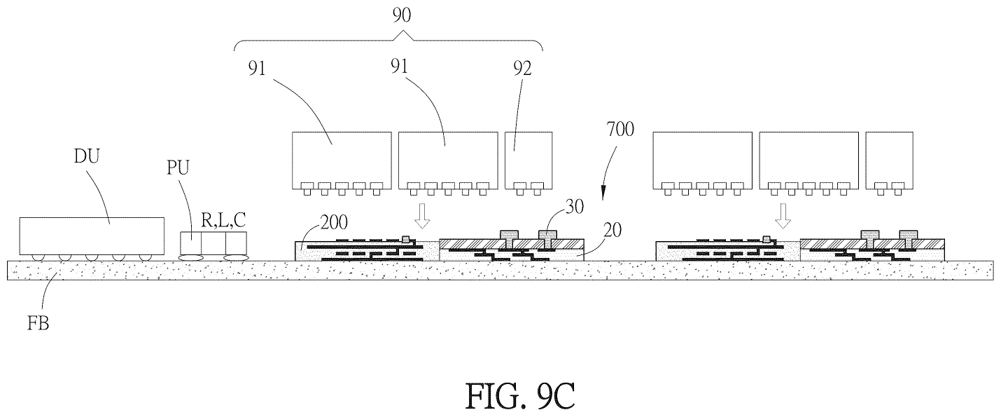

In any embodiment in the current disclosure, an adhesion layer 60″ may be applied between the substrate assemblies and the function board for a planar attachment, see FIG. 9A. In this embodiment, the substrate assembly 4D configured with semiconductor components 90 are illustrated, passive devices, units, or package PU are arranged on the function board FB and driving devices, units, or package DU are arranged as well. Some of the passages or the conductors may pass through the adhesion layer 60″, but not limited thereto. In any embodiment in the current disclosure, the substrate 80 of the substrate assembly maybe include at least hard materials, and the function board FB is further provided with a plurality of sockets SK for the substrate assemblies 4D inserting therein a one-on-one manner, further see FIG. 9B.

In any embodiment in the current disclosure, the function board FB may be a glass substrate, a ceramic substrate, a bismaleimide triazin laminated (BT) substrate, a fiberglass-reinforced epoxy-laminated (FR4) substrate, an build-up film (such as ajinomoto build-up film, ABF) substrate, a Rogers substrate, a PPO substrate, or a polyimide substrate, or any combination including any substrate mentioned-above. Also, the function board itself defines a coefficient of thermal expansion, and a difference of CTE between a corresponding two of them is no greater than 30 ppm/° C.

Here we may know the electronic apparatus in the current disclosure may further incorporated with the '109 provisional, as shown in FIGS. 9A and 9B. FIG. 9A shows the electronic apparatus in that further includes an adhesion layer 60″ between the substrate assemblies and the function board for a planar attachment; the adhesion layer 60″ may be purely non-electrical connection in some embodiments. Some of the passages pass through the adhesion layer 60″ for the electrical connection or optical communication; alternatively, the electrical connection may be accomplished by other approaches, such as an anisotropic conductive film (ACF), but not limited thereto. FIG. 9B shows the electronic apparatus in that the function board is further provided with a plurality of sockets for the substrate assemblies inserting therein a one-on-one manner, wherein the substrate of the substrate assembly includes at least hard materials. Please note that neither the bonding layer nor the adhesion layer is specifically illustrated in this figure. The bonding layer or the adhesion layer may be formed directly between the composite-layered structure and the substrate 80 by high-pressure bonding (or further in combination with high-temperature conditionally). Another embodiment of the electronic apparatus in the current disclosure illustrated in FIG. 9C may embody at least one composite-layered structure, purely with neither the resilient board 14 nor the substrate 80 in this embodiment, disposed on the function board FB directly or indirectly. The various embodiments of the composite-layered structure are referenced and described mentioned above. In these embodiments, the quantity of the composite-layered structures (with or without the substrate) is plural, and the electronic apparatus may further include some packaged ICs DU and passive components PU, such as capacitors, resistors, and inductors, for controlling the signal delivery thereon. Neither the bonding layer nor the adhesion layer is specifically illustrated in this embodiment as well, and the bonding layer or the adhesion layer may be formed directly between the composite-layered structure and the function board FB by high-pressure bonding (or further in combination with high-temperature conditionally).

It should be noted that, in any embodiment disclosed herein, the bonding layer and the adhesion layer are both adhesive in nature, each having bonding properties to firmly secure the respective structures together, and may be formed of materials with either identical or different characteristics.

To be noted, in any embodiment/embodiment mentioned above, in addition to the electrical connection, it would be accomplished to provide an optical communication between corresponding two of the composite-layered structure (with or without the substrate), and the semiconductor components, and vice versa. Therefore, in any embodiment of in the current disclosure, the function board further includes one or more optical engines OE arranged on a corresponding one of optical-trace layers, which is reasonably on top to bottom one of the trace layers. As mentioned above, the optical engine OE is a real unit which is packaged or a virtual unit which is treated as a unit unpackaged. In any embodiment of in the current disclosure, the optical engine OE may include one or more photoelectric conversion members and one or more optical modulator, which are for input/output electrical-optical conversion. The photoelectric conversion member works with the semiconductor components, the conductive-trace layers and further with the function board, and may be an electrical-to-optical component, such as a laser diode; or an optical-to-electrical component, such as a photo sensor. The optical signal may be delivered by an exterior source, such as optical fiber, or an interior source, such as the laser diode. In any embodiment of in the current disclosure, the optical engine OE may include optical trace steering component, which are of adjusting the direction of the optical trace, such as the optical trace from a first waveguide to a second waveguide. In any embodiment of in the current disclosure, the optical engine OE may include the combination of the photoelectric conversion members and one or more optical modulator thereby, and the optical trace steering component.

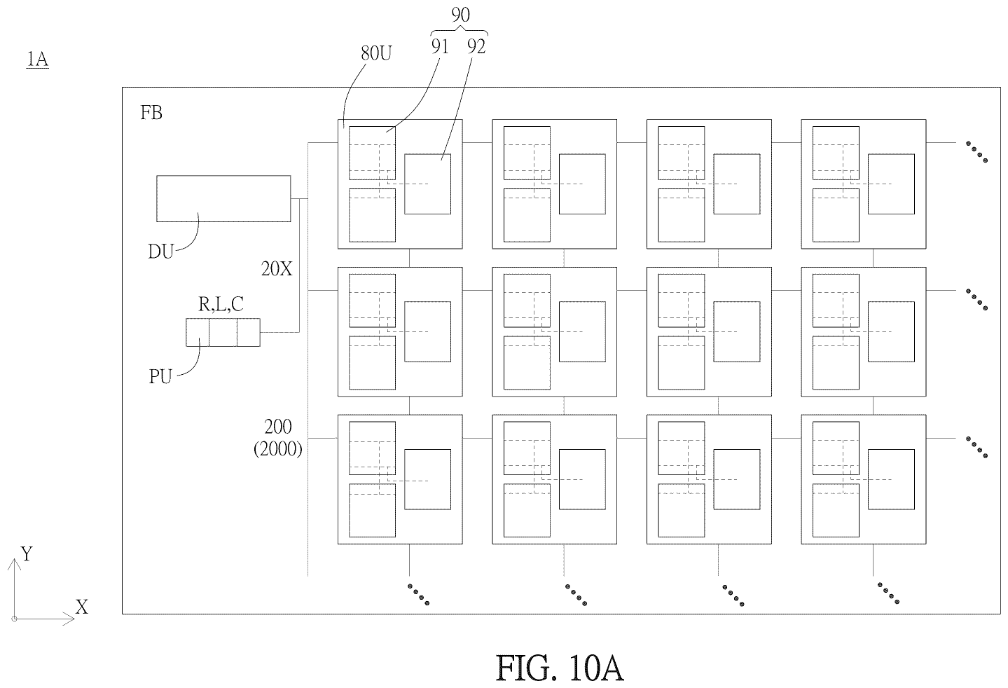

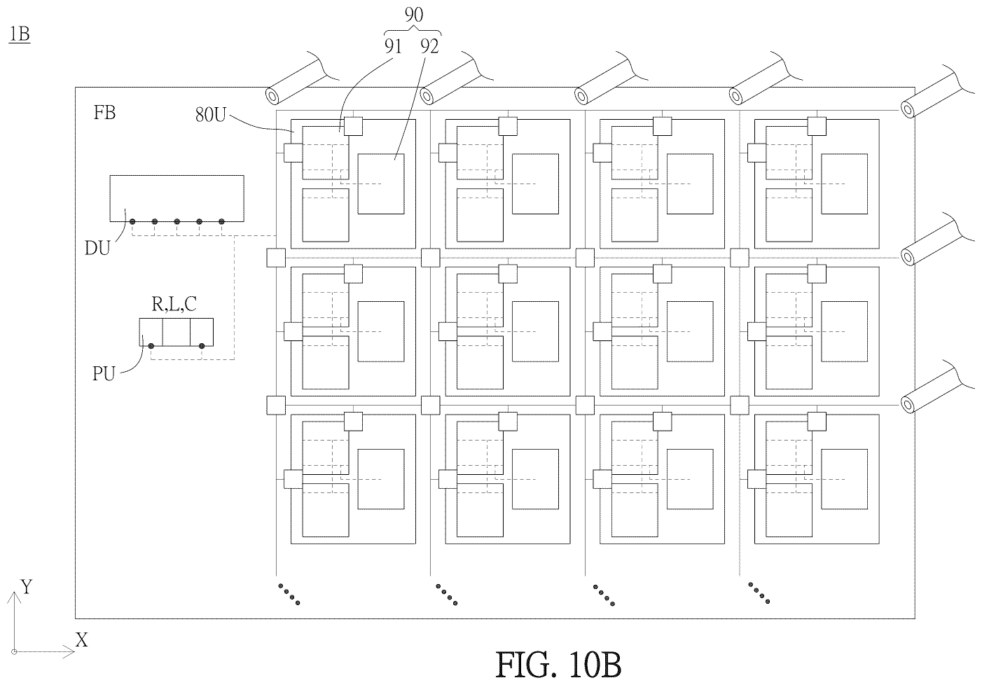

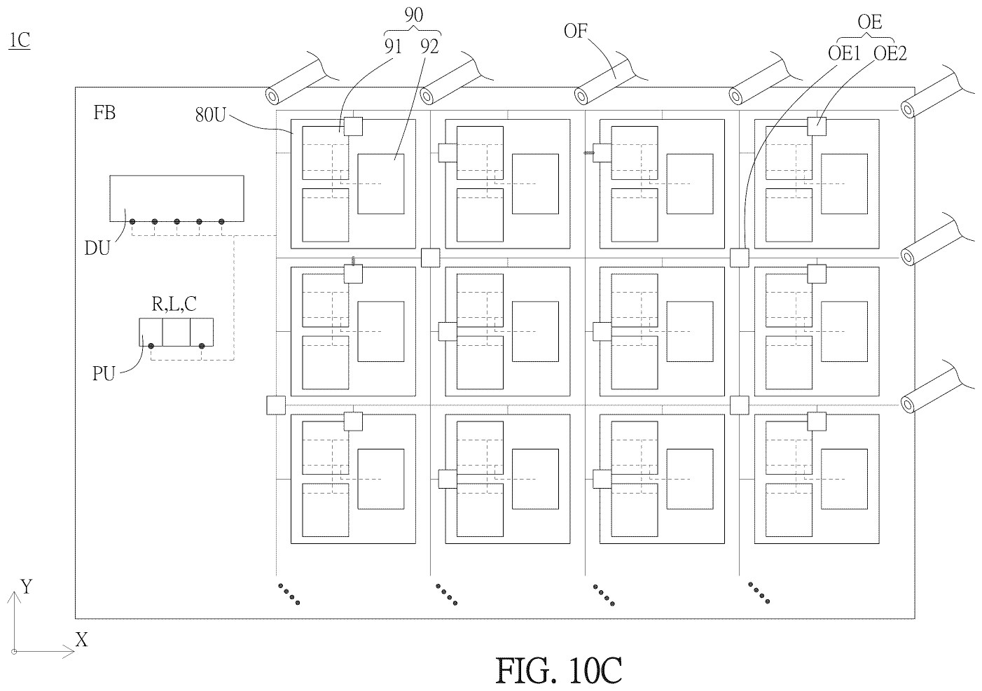

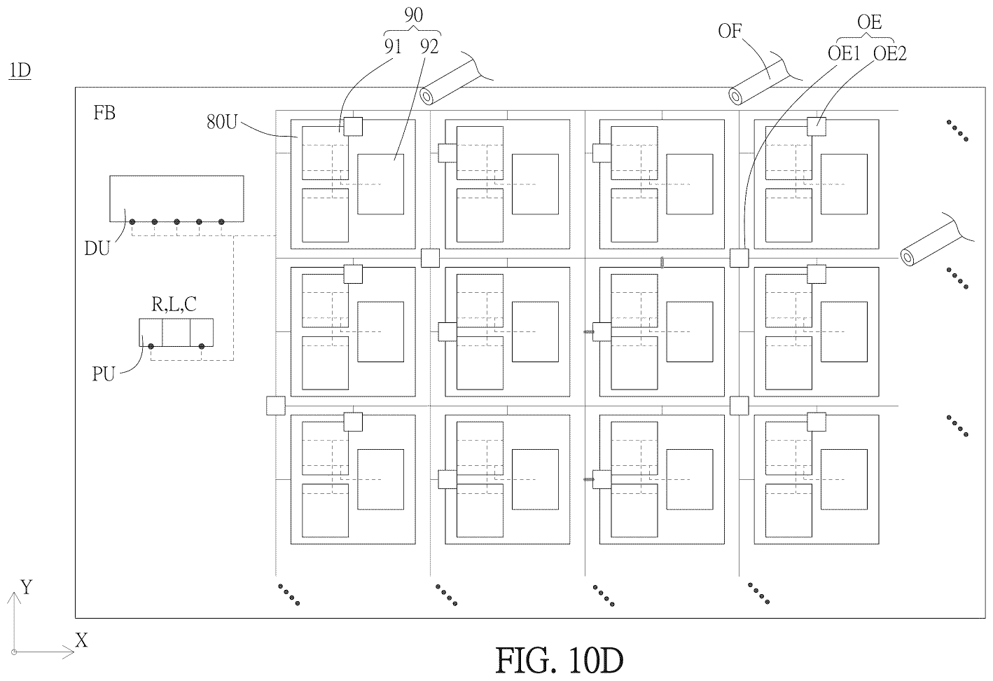

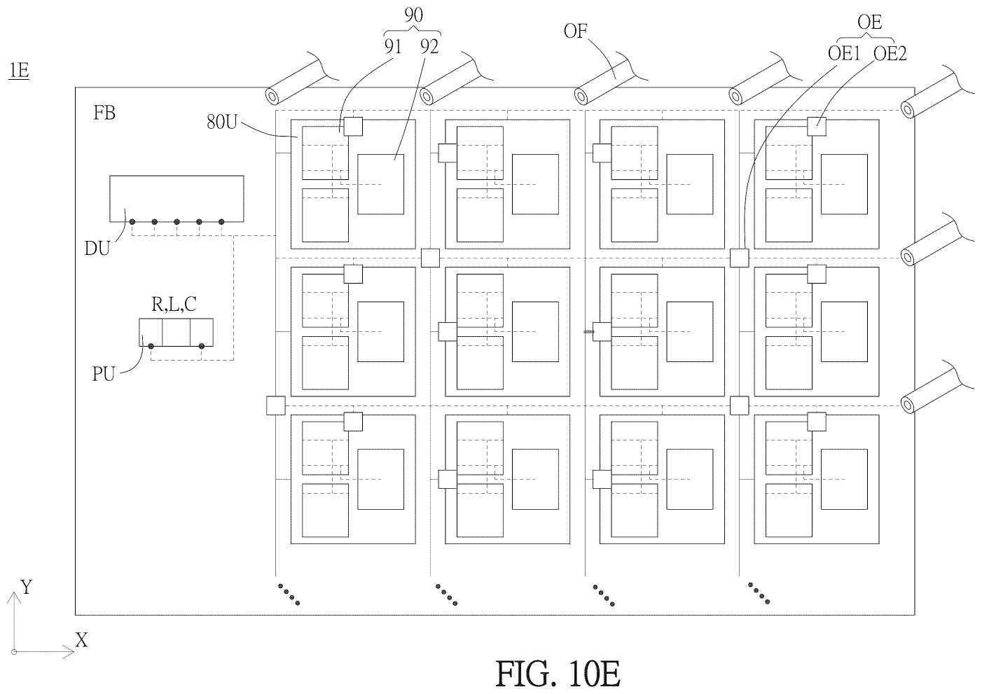

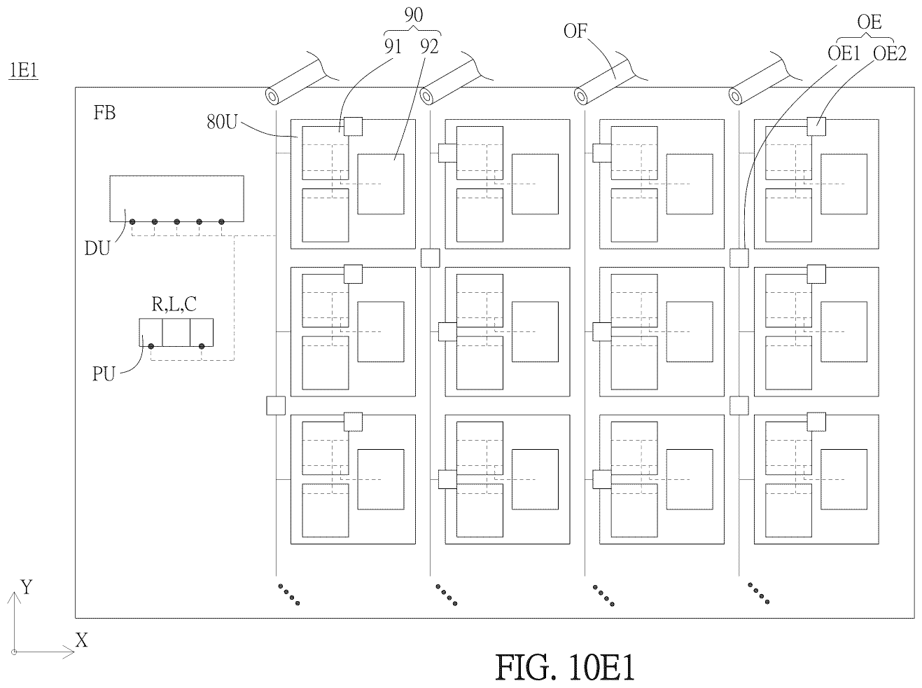

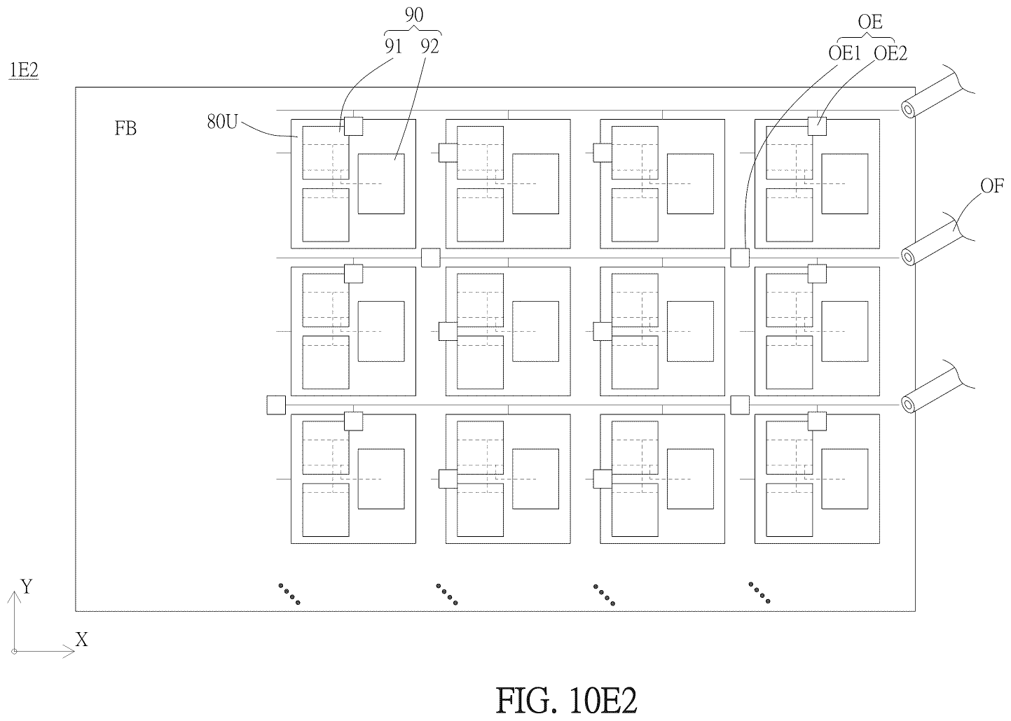

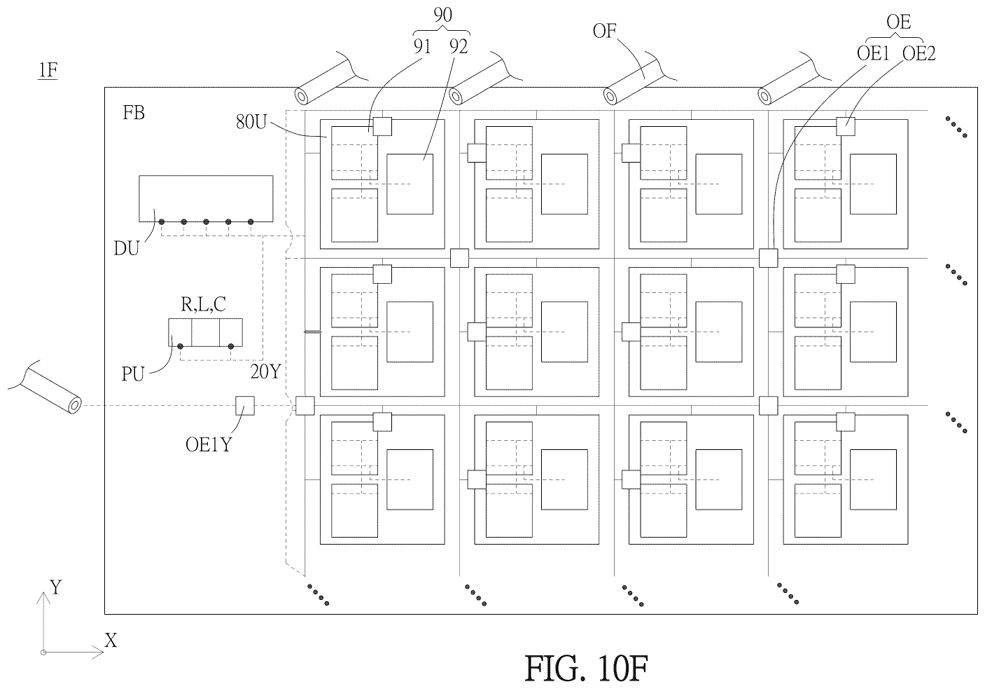

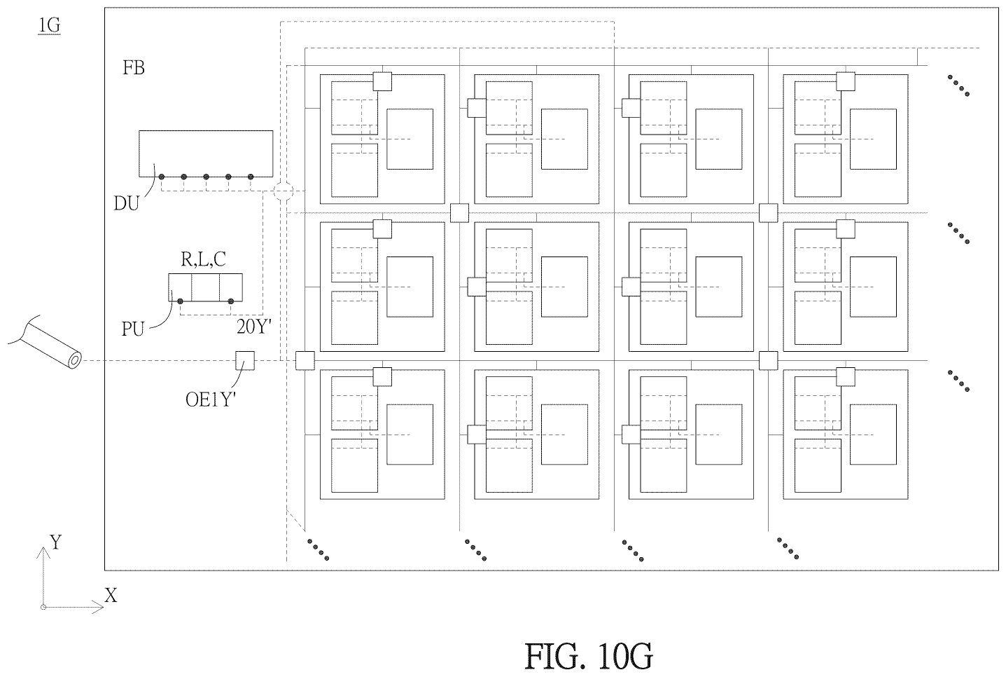

Back to the detailed description of the optical engines OE and optical-trace layers. As we know, the optical-trace layers may be arranged on the substrate or the function board. We take the example of the electronic apparatus 1A, in the current disclosure may further incorporated with the '109 provisional include the optical-trace layer 200/2000 (similar numerals) on the function board FB. The working units 80U could be units where the composite-layered structure sits, or the places where composite-layered structure with its substrate 80 sits. Some packaged ICs DU and passive components PU for controlling the signal delivery is arranged thereon, please see FIG. 10A. We can see the optical-trace layer 200/2000 as a single optical-trace layer, and the optical-trace layer may have a plurality of the optical traces. Some of the optical traces extend and parallel with in a first direction D1 along the composite-layered structure, and some of the optical traces extend and parallel with in a second direction D2 along the composite-layered structure, and these of the optical traces are treated as the main optical traces. The first direction DI is non-parallel with the second direction D2 or not. Some of the optical traces may be further allocated in correspondence with the composite-layered structure (with or without the substrate), and treated as the sub optical traces, which are optional. In some embodiments, the sub optical traces may communicate with at least one of the semiconductor components 90 with the main optical traces. In some embodiments, the sub optical traces may communicate with either two of the semiconductor components 91, 92. The circuit unit 20X can be conductive trace or the optical trace, which is capable of controlling the optical-trace layer 200/2000, through an electrical-optical conversion circuit/unit or not.

Here are some embodiments for the optical engines OE arranged upon the optical-trace layer. In one embodiment, one or more optical engines OE are arranged on a corresponding one of optical-trace layers in FIG. 10B, in which the optical traces may further electrically connect to the semiconductor components 90 through the optical engine(s) OE for input/output electrical-optical conversion or steer the direction of the optical trace. Some of the optical engine(s) OE control(s)/steer(s) the optical signal of the optical traces in either or both of the first direction D1 and the second direction D2; some of the optical engine(s) OE control(s)/steer(s) the optical signal in a third direction D3 (perpendicular direction) perpendicular to the composite-layered structures. When it says the optical engine(s) OE1 control(s)/steer(s), acting as a light redirector, it means the optical signal is steered and change to next direction from the previous direction. When it says the optical engine(s) OE2 control(s)/converts, acting as a photoelectric converter, it means the optical signal is converted to the electrical signal, or vice versa. To be noted, the delivery direction of the electrical signal is not limited. Here we talk about the word “control” indicating the action at least including steering or converting, but not limited; the optical engine(s) OE is (are) of at least one function mentioned above. In this embodiment, each of the main optical traces is provided with the edge coupler with an optical fiber OF.

To be noted, the entrance of the optical signal may be arranged on either or both of the composite-layered structures and the function board.

We take the optical trace layer on the function board for example in FIG. 10C. Differing from FIG. 10B, the optical engines OE1 control/steer the optical signal of the optical traces are not fully distributed in each intersection where the main optical traces cross, in either or both of the first and second directions D1, D2; the optical engines OE2 control/convert the optical signal of the optical traces are not fully distributed in entrance into semiconductor components 90, in either or both of the first and second directions D1, D2.

We take the optical trace layer on the function board for example in FIG. 10D. Differing from FIG. 10C, not all of the main optical traces are provided with the edge coupler with an optical fiber OF.

We take the optical trace layer on the function board for example in FIGS. 10E, 10E1 and 10E2. Differing from FIG. 10D, FIG. 10E shows multiple optical-trace layers, in which some of the optical traces of one of the optical-trace layers extend in a first direction DI along the composite-layered structure, and some of the optical traces of another one of the optical-trace layers extend in a second direction D2 along the composite-layered structure. Some of the optical engines OE 1, works as steer the optical signal of the optical traces to either or both of the first direction DI and the second direction D2, or further vertical to the third direction D3 (perpendicular direction) from an original point; Some of the optical engines OE 2 works as converts the optical signal to the electrical signal, or vice versa. FIG. 10E1 shows that the optical signal entering via the optical fiber OF is primarily transmitted in the first direction D1 to the corresponding working units 80U, while FIG. 10E2 shows that the optical signal entering via the optical fiber OF is primarily transmitted in the second direction D2 to the corresponding working units 80U.

To be noted, the optical engines OE1 may sit at a plurality of intersections where the optical traces cross in the first direction and second direction, and may be arranged on the same or different optical-trace layers. To be noted, either or all of the optical-trace layers may arrange the optical engines OE1/OE2; the positions where the optical engines OE on one optical-trace layer may coincide with the optical engines OE on another optical-trace layer(s) or not.

We take the optical trace layer on the function board for example in FIG. 10F. Here we go for the quantity of the optical layer may be single or plural, and not irritate the logic of the arrangement in this embodiment. A demultiplexer-like type of optical circuit 20Y and an optical engine OE1Y are arranged aside the main optical traces, an exterior single one optical source, such as an optical fiber OF, may be provided thereto for example in FIG. 10F, and may be controlled by the packaged IC. The optical engine OE1Y controls the optical signals along the main optical traces in the first direction D1.

To be noted, an interior optical source in any embodiment in the current disclosure may replace the previous one.

We take the optical trace layer on the function board for example in FIG. 10G, similar to the embodiment in FIG. 10F. The optical engines OE1Y′, except controlling the optical signals along the main optical traces in the first direction D1, further control the optical signals along the main optical traces in the first direction D2 in a demultiplexer-like manner, and a demultiplexer-like type of optical circuit 20Y′ is formed.

Here we also can understand there are the manufacture approaches for various embodiments of the electronic apparatus, in which the function board are at least with a composite-layered structure and the semiconductor components. How the electronic apparatus is accomplished may be divided into at least four approaches, here we go for further comprehension, and please note there may be no function board illustrated if we focus on the process of various substrate assemblies but description instead.

A first approach is the substrate assembly with the composite-layered structures and the substrate, and the substrate assembly is then transfer upon the function board or provided with the semiconductor components. During the first approach, the optical trace layers and the conductive-trace layers may be processed in individual processes, and both of them are with the substrate in one embodiment, which is easier for understanding in comparison with another embodiment mentioned later. In another embodiment, either or both of the optical trace layers and the conductive-trace layers are with resilient board.

A second approach is the substrate assembly with the composite-layered structures and the substrate, and the substrate assembly is then transfer upon the function board or provided with the semiconductor components. Differing from the first approach, only either of the optical trace layers and the conductive-trace layers or neither one is with the substrate.

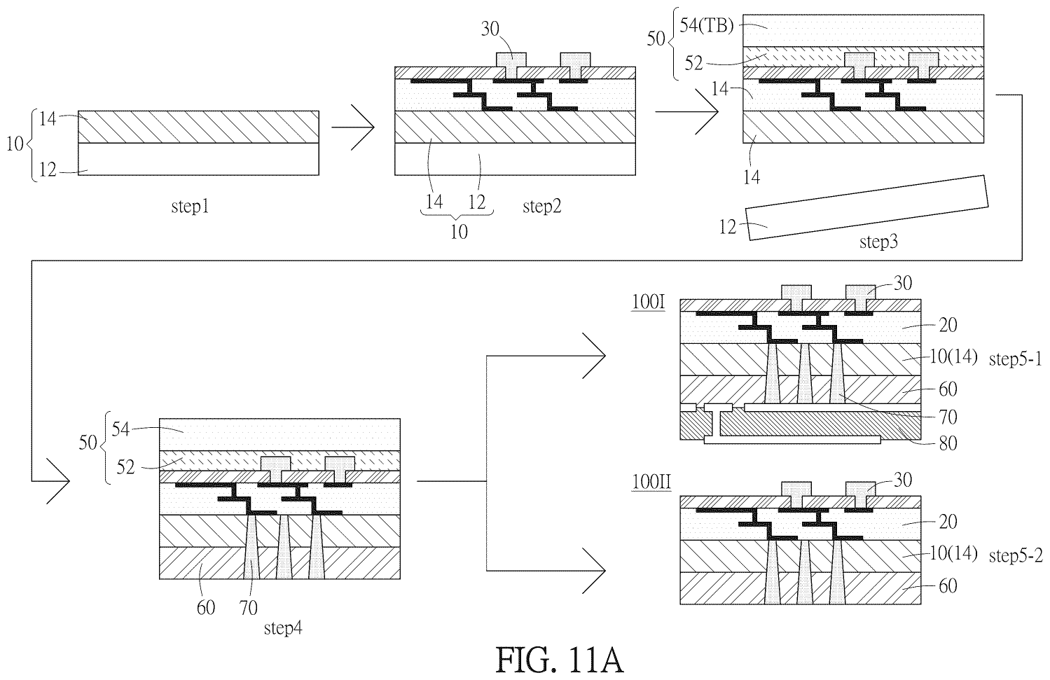

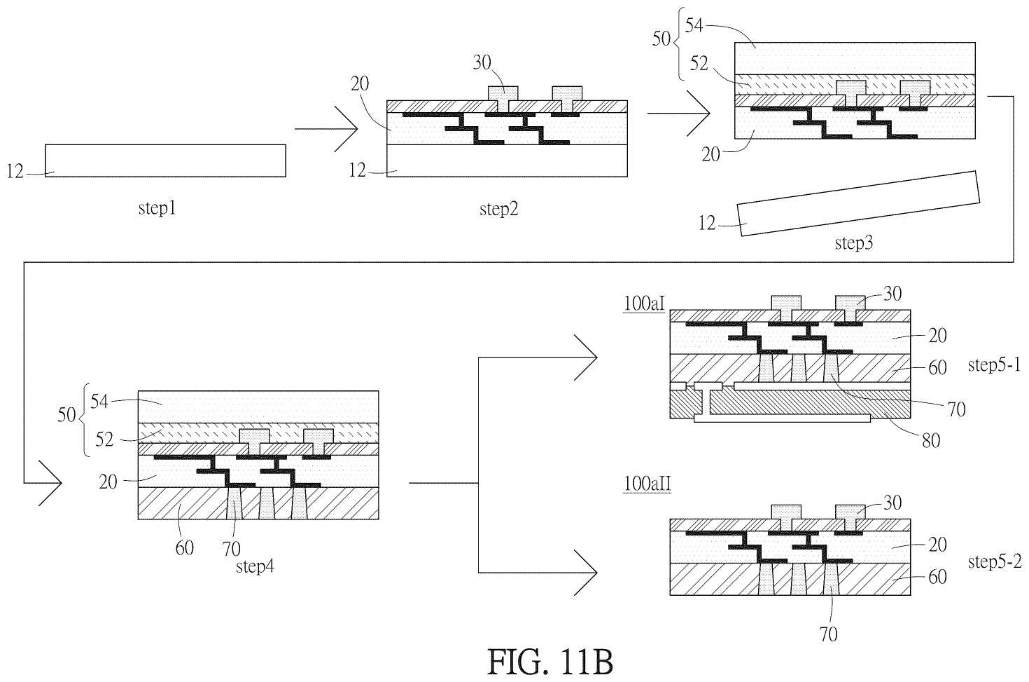

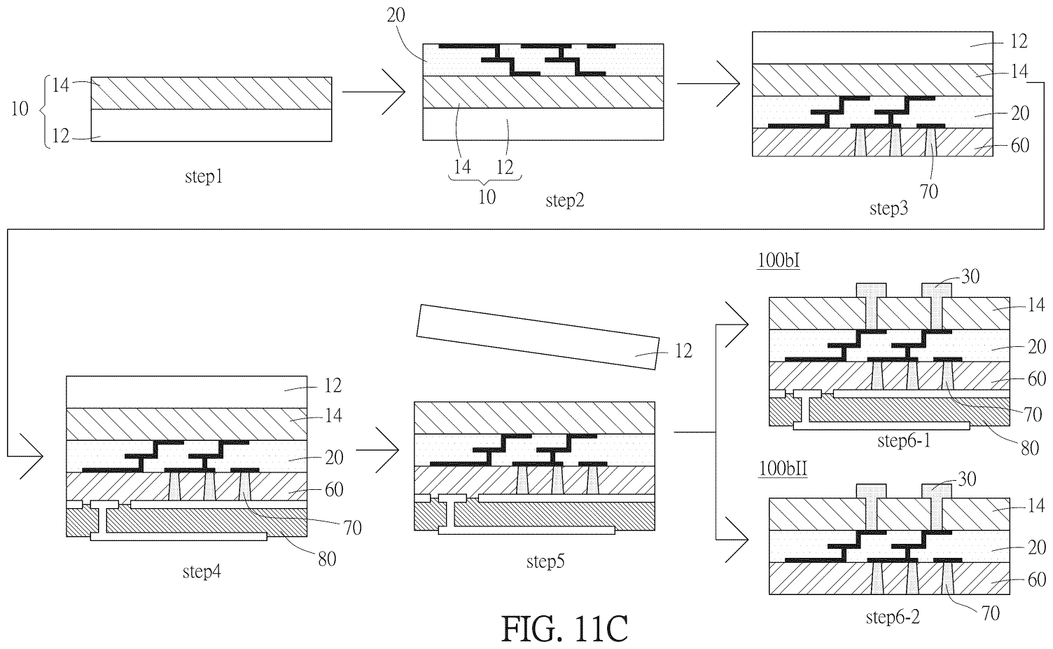

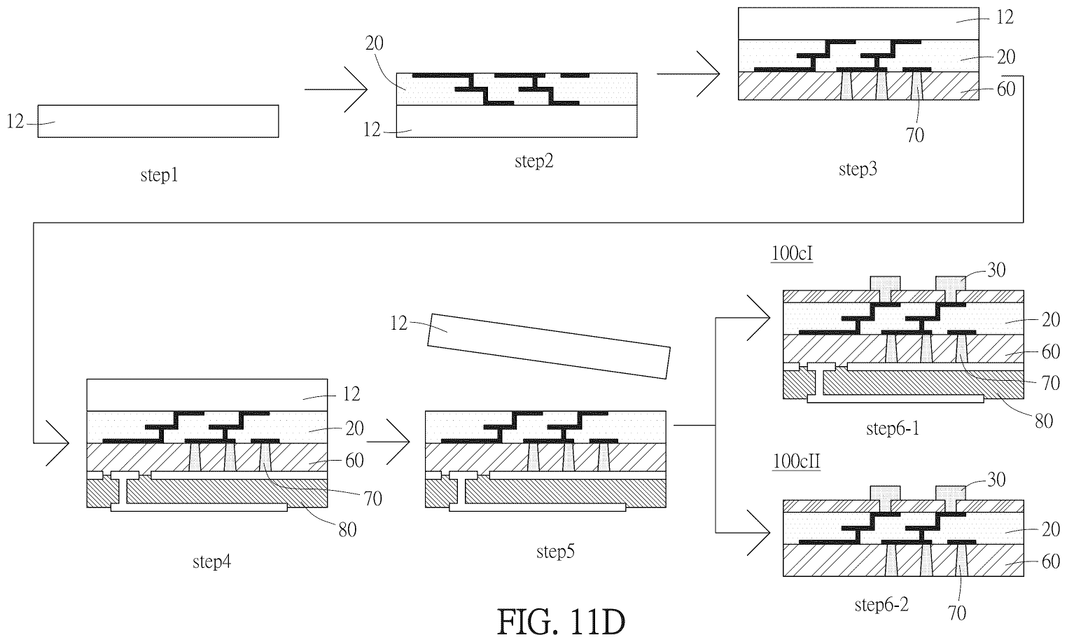

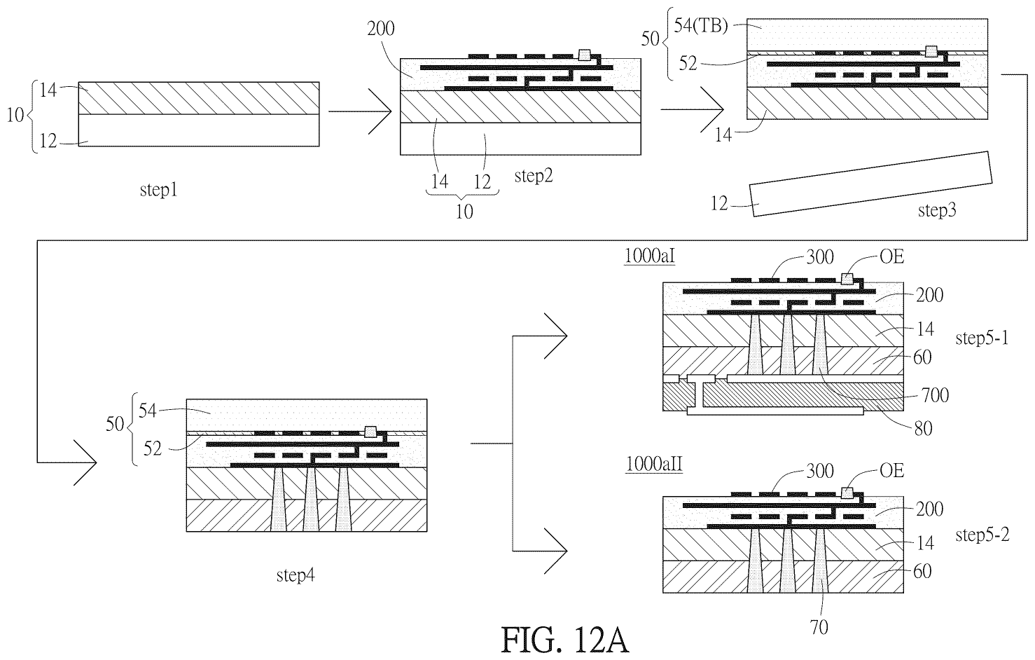

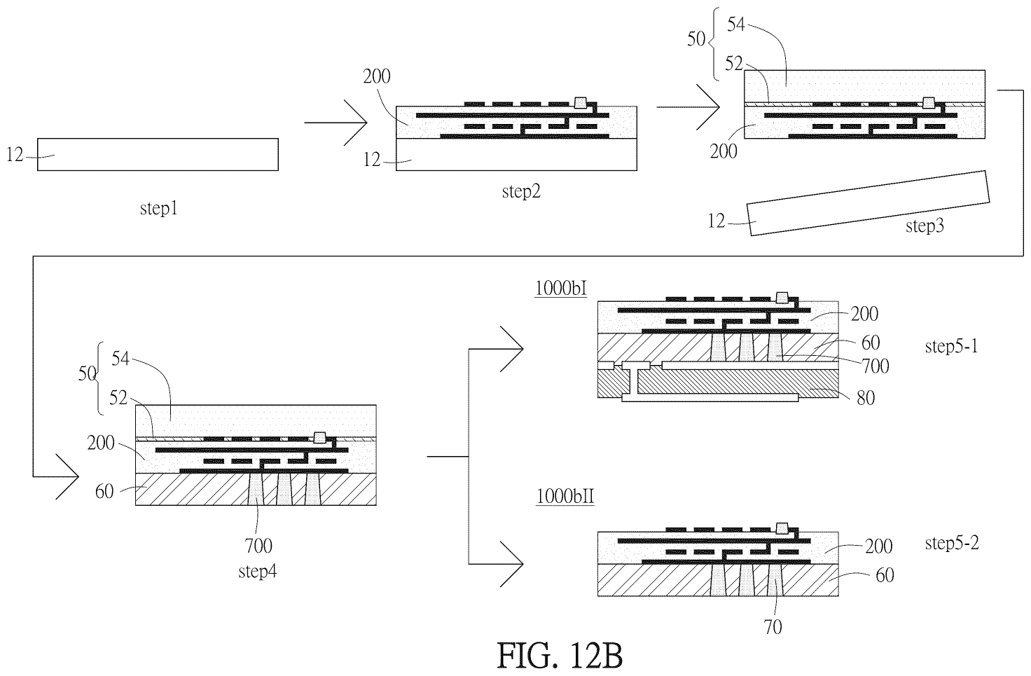

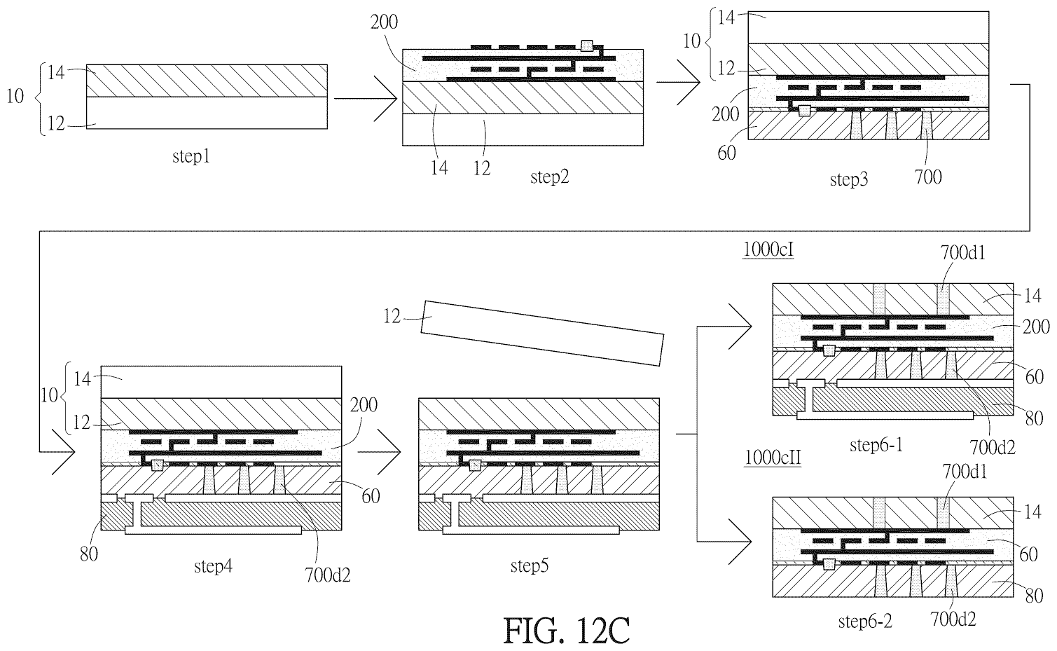

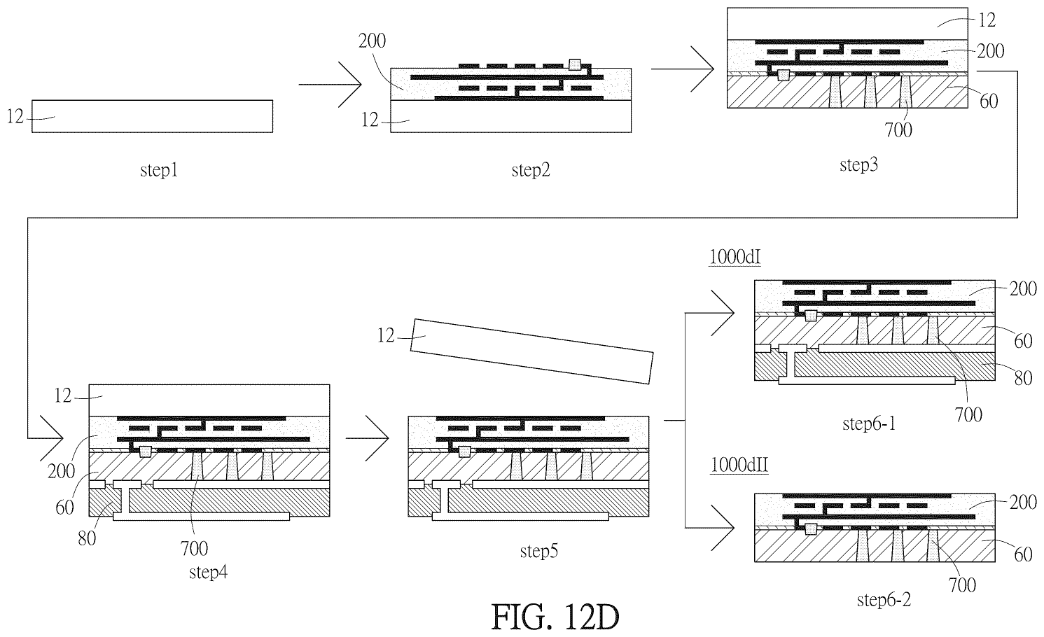

See FIGS. 11A to 11D and 12A to 12D, during these drawings, an original board 10 may include a resilient board 14 on a rigid board 12, or the original board 10 includes the rigid board 12 merely. We should know both of the resilient board 14 and the rigid board 12 may be a single or composite substrate. The composite-layered structure includes at least one or more optical-trace layers 400′ (or similar numerals), and may further include one or more conductive-trace layers 40′ (or similar numerals). The composite-layered structures 100I, 100II in FIG. 11A are structures that conductive-trace layers 40′ with or without substrate 80 processed individually. Step 1 depicts the original board 10 including a resilient board 14 on a rigid board 12. Step 2 depicts a conductive-trace layer 20 arranged on the resilient board 14 and a conductive pad 30 is formed on the conductive-trace layer 20. Step 3 depicts a temporary bonding carrier structure 50 including a temporary bonding carrier 54 (serves as same as the temporary bonding carrier TB) and a release layer 52 between the temporary bonding carrier 54 and the conductive-trace layer 20, and the rigid board 12 is released from the resilient board 14. Step 4 depicts a bonding layer 60 arranged to the resilient board 14, multiple conductors 70 penetrating through the bonding layer 60 and the resilient board 14 and electrically connecting the conductive-trace layer 20. Step 5-1 depicts the temporary bonding carrier 54 is released from the conductive-trace layer 20 through vanishing the release layer 52 by laser lift off process, and a substrate 80 arranged beneath the bonding layer 60 and connect to the resilient board 14. Step 5-2 also depicts the temporary bonding carrier 54 is released from the conductive-trace layer 20 through vanishing the release layer 52 by laser lift off process, but there is no substrate 80 arranged beneath the bonding layer 60.

The composite-layered structures 100aI, 100aII in FIG. 11B are structures that conductive-trace layers 40a′ with or without substrate 80 processed individually. Step 1 depicts the original board 10 including a rigid board 12 merely. Step 2 depicts a conductive-trace layer 20 arranged on the rigid board 12 and a conductive pad 30 is formed on the conductive-trace layer 20. Step 3 depicts a temporary bonding carrier structure 50 including a temporary bonding carrier 54 (referred the temporary bonding carrier TB) and a release layer 52 between the temporary bonding carrier 54 and the conductive-trace layer 20, and the rigid board 12 is released from the conductive-trace layer 20. Step 4 depicts a bonding layer 60 arranged to the conductive-trace layer 20 directly, multiple conductors 70 penetrating through the bonding layer 60 and electrically connecting the conductive-trace layer 20. Step 5-1 depicts the temporary bonding carrier 54 is released from the conductive-trace layer 20 through vanishing the release layer 52 by laser lift off process, and a substrate 80 arranged beneath the bonding layer 60 and connect to the conductive-trace layer 20. Step 5-2 also depicts the temporary bonding carrier 54 is released from the conductive-trace layer 20 through vanishing the release layer 52 by laser lift off process, but there is no substrate 80 arranged beneath the bonding layer 60.

The composite-layered structures 100bI, 100bII in FIG. 11C are structures that conductive-trace layers 40b′ with or without substrate 80 processed individually. Step 1 depicts the original board 10 including a resilient board 14 on a rigid board 12. Step 2 depicts a conductive-trace layer 20 arranged on the resilient board 14 and a conductive pad 30 is formed on the conductive-trace layer 20. Step 3 depicts a bonding layer 60 arranged to the conductive-trace layer 20, multiple conductors 70 penetrating through the bonding layer 60 and electrically connecting the conductive-trace layer 20. Step 4 depicts a substrate 80 physically connecting the conductive-trace layer 20 through the bonding layer 60 and electrically connecting the conductive-trace layer 20 through the conductors 70. Step 5 depicts the temporary bonding carrier 54 is released from the conductive-trace layer 20 through vanishing the release layer 52 by laser lift off process. Step 6-1 depicts the composite-layered structure 100bI accomplished after the step 5. Step 6-2 depicts the composite-layered structure 100bII accomplished by the temporary bonding carrier 54 is released from the conductive-trace layer 20 through vanishing the release layer 52 by laser lift off process after the step 3.

The composite-layered structures 100cI, 100cII in FIG. 11D are structures that conductive-trace layers 40c′ with or without substrate 80 processed individually. Step 1 depicts the original board 10 including a rigid board 12 merely. Step 2 depicts a conductive-trace layer 20 arranged on the rigid board 12 and a conductive pad 30 is formed on the conductive-trace layer 20. Step 3 depicts a bonding layer 60 arranged to the conductive-trace layer 20, multiple conductors 70 penetrating through the bonding layer 60 electrically connecting the conductive-trace layer 20. Step 4 depicts a substrate 80 physically connecting the conductive-trace layer 20 through the bonding layer 60 and electrically connecting the conductive-trace layer 20 through the conductors 70. Step 5 depicts the temporary bonding carrier 54 is released from the conductive-trace layer 20 through vanishing the release layer 52 by laser lift off process. Step 6-1 depicts the composite-layered structure 100cI accomplished after the step 5. Step 6-2 depicts the composite-layered structure 100cII accomplished by the temporary bonding carrier 54 is released from the conductive-trace layer 20 through vanishing the release layer 52 by laser lift off process after the step 3.

The optical-trace layers 400′ with or without substrate 80, as illustrated in FIGS. 12A to 12D, can be performed in a manner corresponding to that shown in FIGS. 11A to 11D, with the only difference being that the conductive-trace layer 20 is replaced by the optical-trace layer 200. The composite-layered structures comprising only optical-trace layers 400′, such as 1000I and 1000II shown in FIG. 12A, can likewise be fabricated using the same processes as those for the composite-layered structures 1001 and 100II in FIG. 11A, by substituting the conductive-trace layer 20 with the optical-trace layer 200.

Similarly, FIGS. 12B to 12D can be processed in the same manner, and the composite-layered structures 1000aI, 1000aII, 1000bI, 1000bII, 1000cI, 1000cII are accomplished.

The results of the conductive-trace layers 40′ in FIGS. 11A to 11D can combined with the results of the optical-trace layers 400′ in FIGS. 12A to 12D, for further achieving the substrate assemblies and electronic apparatus (by further applying the function board FB) according to the first and second approaches.

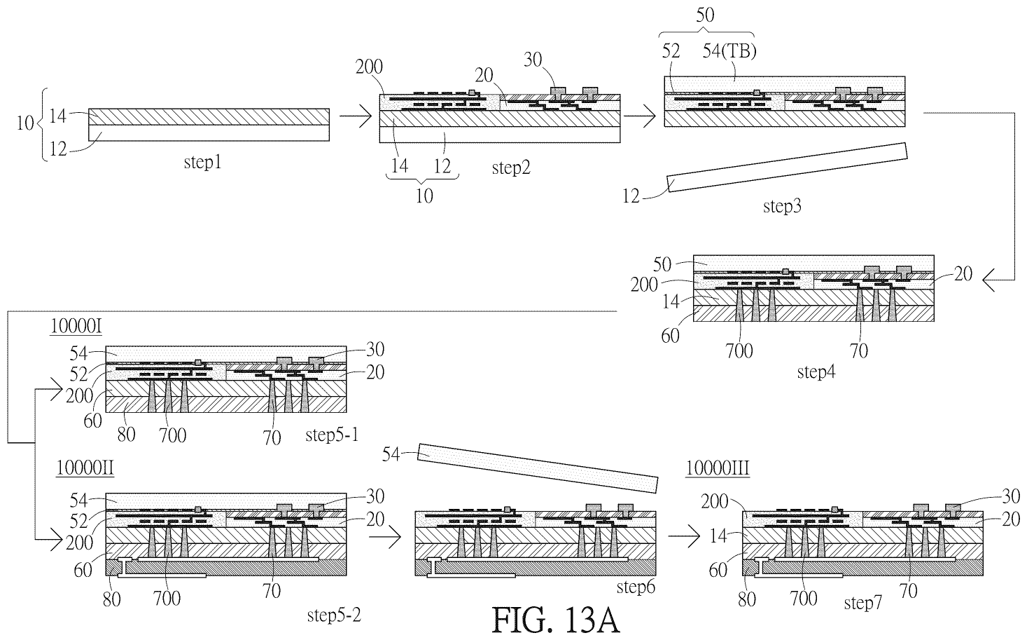

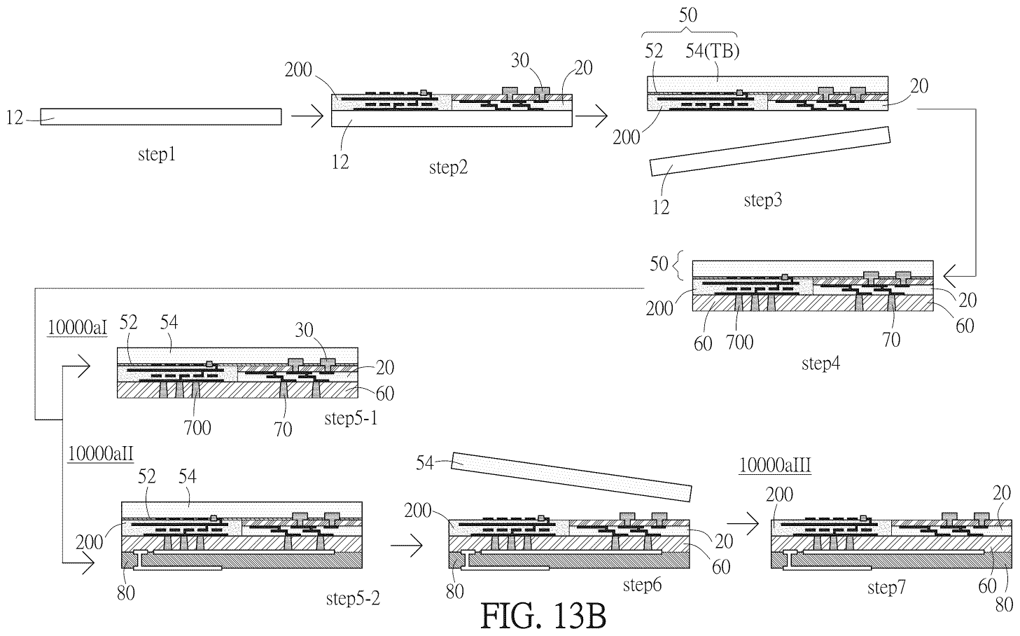

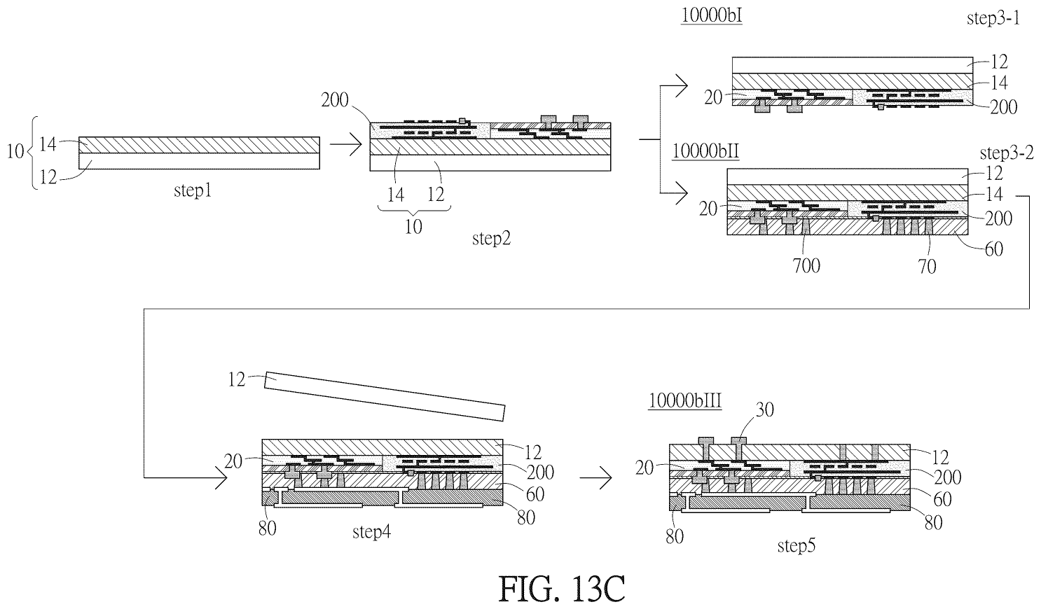

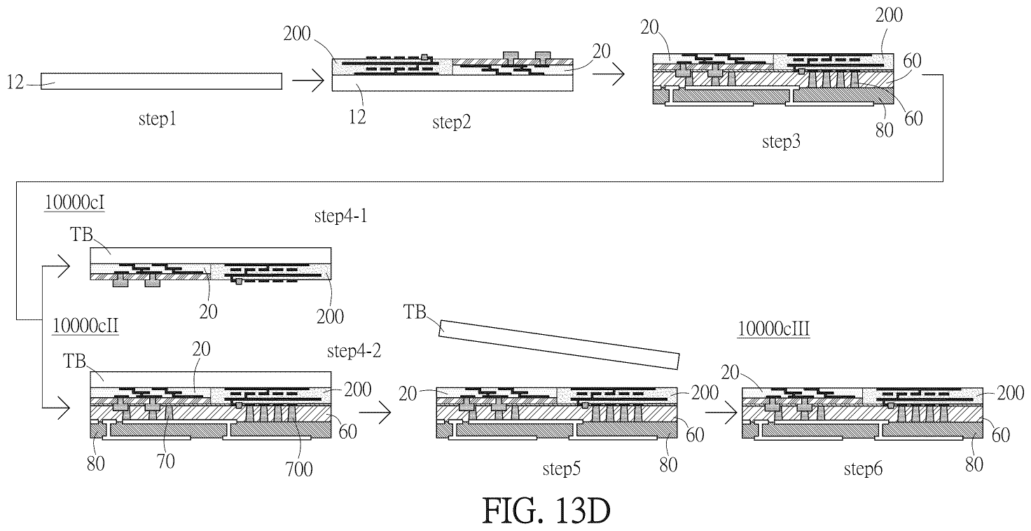

There are a third approach provided, the composite-layered structures with the substrate (or not) to form the substrate assembly and then either or both to transfer upon the function board FB and to be provided with the semiconductor components. Differing from the second approach, the optical-trace layers and the conductive-trace layers are formed on the substrate 80 (or not) in the same proceedings, in a coplanar manner or a stacked manner. FIGS. 13A to 13D shows the coplanar-manner process. The composite-layered structure 4000′ (or similar numerals) includes one or more conductive-trace layers optical-trace layers, which can be formed in the same proceedings on one substrate/board/carrier; normally the conductive-trace layer(s) is (are) used for interacting with the optical-trace layer(s) in a mixed manner, which means no significant individual regions for these two layers from the top view.

The composite-layered structures 10000I, 10000II, 10000III in FIG. 13A are structures that composite-layered structures 2000 with or without substrate 80 processed individually. Step 1 depicts the original board 10 including a resilient board 14 on a rigid board 12. Step 2 depicts a composite-layered structures 2000, configured with a conductive-trace layer 20 and optical-trace layer 200, arranged on the resilient board 14 and a conductive pad 3000 is formed on the conductive-trace layer 20. Step 3 depicts a temporary bonding carrier structure 50 including a temporary bonding carrier 54 (referred the temporary bonding carrier TB) and a release layer 52 between the temporary bonding carrier 54 and the conductive-trace layer 20, and the rigid board 12 is released from the resilient board 14. Step 4 depicts a bonding layer 60 arranged to the resilient board 14, multiple conductors 70 penetrating through the bonding layer 60 and the resilient board 14 and electrically connecting the conductive-trace layer 20. Step 5-1 depicts the temporary bonding carrier 54 is released from the conductive-trace layer 20 through vanishing the release layer 52 by laser lift off process, and there is no substrate 80 arranged beneath the bonding layer 60; at this stage, the composite-layered structures 10000I in Step 5-1 can be applied upon the function board in the later process. Step 5-2 also depicts the temporary bonding carrier 54 is released from the conductive-trace layer 20 through vanishing the release layer 52 by laser lift off process, and a substrate 80 arranged beneath the bonding layer 60; at this stage, the composite-layered structures 10000II in Step 5-2 can be applied upon the function board in the later process, and further composite-layered structures 10000III in Step 7 can be accomplished after the temporary bonding carrier 54 is released from the conductive-trace layer 20 through vanishing the release layer 52 by laser lift off process in Step 6.

The composite-layered structures 10000aI, 10000aII, 10000aIII in FIG. 13B are structures that composite-layered structures 2000 with or without substrate 80 processed individually. Step 1 depicts the original board 10 including a rigid board 12 merely. Step 2 depicts a composite-layered structures 2000, configured with a conductive-trace layer 20 and optical-trace layer 200, arranged on the rigid board 12 and a conductive pad 3000 is formed on the conductive-trace layer 20. Step 3 depicts a temporary bonding carrier structure 50 including a temporary bonding carrier 54 (TB) and a release layer 52 between the temporary bonding carrier 54 and the conductive-trace layer 20, and the rigid board 12 is released from the resilient board 14. Step 4 depicts a bonding layer 60 arranged to the composite-layered structures 2000, multiple conductors 70 penetrating through the bonding layer 60 and electrically connecting the composite-layered structures 2000. Step 5-1 depicts the temporary bonding carrier 54 is released from the conductive-trace layer 20 through vanishing the release layer 52 by laser lift off process, and there is no substrate 80 arranged beneath the bonding layer 60; at this stage, the composite-layered structures 10000aI in Step 5-1 can be applied upon the function board in the later process. Step 5-2 also depicts the temporary bonding carrier 54 is released from the conductive-trace layer 20 through vanishing the release layer 52 by laser lift off process, and a substrate 80 arranged beneath the bonding layer 60; at this stage, the composite-layered structures 10000aII in Step 5-2 can be applied upon the function board in the later process, and further composite-layered structures 10000aIII in Step 7 can be accomplished after the temporary bonding carrier 54 is released from the conductive-trace layer 20 through vanishing the release layer 52 by laser lift off process in Step 6.

The composite-layered structures 10000bI, 10000bII, 10000bIII in FIG. 13C are structures that composite-layered structures 2000 with or without substrate 80 processed individually. Step 1 depicts the original board 10 including a resilient board 14 on a rigid board 12. Step 2 depicts a composite-layered structures 2000, configured with a conductive-trace layer 20 and optical-trace layer 200, arranged on the resilient board 14 and a conductive pad 3000 is formed on the conductive-trace layer 20. Step 3-1 depicts a temporary bonding carrier structure 50 including a temporary bonding carrier 54 (TB) and a release layer 52 between the temporary bonding carrier 54 and the conductive-trace layer 20; at this stage, the composite-layered structures 10000bI in Step 3-1 can be applied upon the function board in the later process. Step 3-2 depicts a bonding layer 60 arranged to the resilient board 14, multiple conductors 70 penetrating through the bonding layer 60 and the resilient board 14 and electrically connecting the conductive-trace layer 20; at this stage, the composite-layered structures 10000bII in Step 3-2 can be applied upon the function board in the later process. Step 4 depicts a substrate 80 arranged beneath the bonding layer 60, and the rigid board 12 is released from the resilient board 14; at this stage, the composite-layered structures 10000II in Step 5 can be applied upon the function board in the later process, and further composite-layered structures 10000bIII in Step 7 can be accomplished after the rigid board 12 is released in Step 4.

The composite-layered structures 10000cI, 10000cII, 10000cIII in FIG. 13D are structures that composite-layered structures 2000 with or without substrate 80 processed individually. Step 1 depicts the original board 10 including a rigid board 12 merely. Step 2 depicts a composite-layered structures 2000, configured with a conductive-trace layer 20 and optical-trace layer 200, arranged on the rigid board 12 and a conductive pad 3000 is formed on the conductive-trace layer 20. Step 3-1 depicts a result structure in Step 2 upside down; at this stage, the composite-layered structures 10000cI in Step 3-1 can be applied upon the function board in the later process. Step 3-2 depicts a bonding layer 60 arranged to the composite-layered structures 2000, multiple conductors 70 penetrating through the bonding layer 60 and electrically connecting the composite-layered structures 2000; at this stage, the composite-layered structures 10000cII in Step 3-2 can be applied upon the function board in the later process. Step 4 depicts a substrate 80 arranged beneath the bonding layer 60. Step 5 depicts the rigid board 12 released from the composite-layered structures 2000 by laser lift off process; at this stage, the composite-layered structures 10000cIII in Step 6 can be applied upon the function board in the later process.

The results of the conductive-trace layers 4000′ in FIGS. 13A to 13D can be utilized alone for achieving the substrate assemblies in the third approach. Or, the results of the conductive-trace layers 4000′ in FIGS. 13A to 13D can be mixed with wither or both of the results of the conductive-trace layers 40′ in FIGS. 11A to 11D and the results of the optical-trace layers 400′ in FIGS. 12A to 12D, for further achieving the substrate assemblies in another approaches.

It's reasonably understood that there could be any combination among the first groups to the third approach.

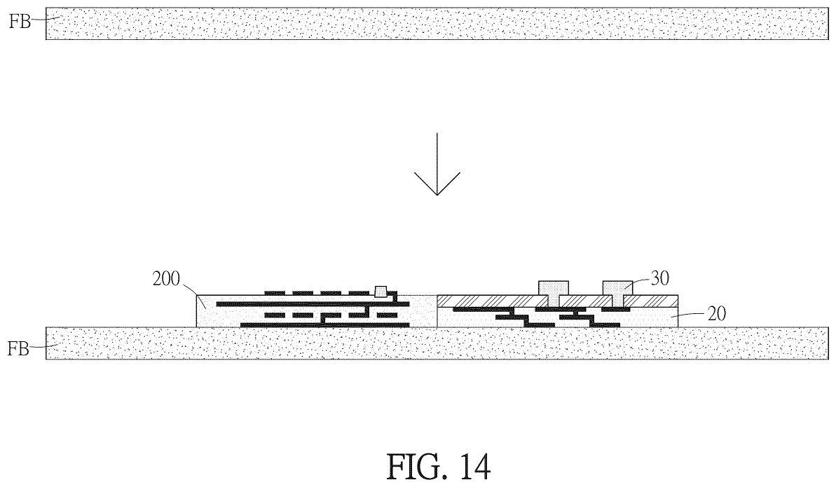

A fourth approach is the composite-layered structures directly formed on the function board, which means there is not substrate applied therefore, and before or after it, the semiconductor components can be arranged on the composite-layered structures. The optical trace layers 200 and the conductive-trace layers 20 are formed on the function board FB in the same proceedings in a coplanar manner, or the optical trace layers 200 and the conductive-trace layers 20 are formed on the function board FB in a stacked manner. See FIG. 14, the optical trace layers and the conductive-trace layers are in the coplanar manner. Neither the bonding layer nor the adhesion layer is specifically illustrated in this embodiment as well, and the bonding layer or the adhesion layer may be formed directly between the composite-layered structure and the function board FB by high-pressure bonding (or further in combination with high-temperature conditionally).

As an example, the fourth approach will be further described below for manufacturing the electronic apparatus. First, a TFT panel process can be utilized to create high-precision (2 μm), large-area, and low-cost conductive-trace layers (here referring to the RDL layer) on a resilient board (such as a PI board) laminated on a rigid board (such as a glass board), or directly on the rigid board. The structure is then cut into clusters (containing several units) and lifted off from the glass board. The optical-trace layers (serving as optical links, including at least waveguides and/or optical fibers) can also be pre-fabricated on the function board (packaging substrate grade). The clusters are then assembled onto the function board, and the electrical connections are completed to form the electronic apparatus. Multiple CoR (Chip on ultra-fine RDL, i.e., semi-finished CoWoS-R) units can be bonded onto the electronic apparatus, enabling the creation of a large-scale integrated system on the clustered units of the electronic apparatus. This hierarchical architectural design helps manage stress and maintain accuracy, while a moderate cluster size ensures precise alignment of the cluster units (PI clusters) with the function board. Furthermore, redundancy design can be incorporated to address concerns related to low yield.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A substrate assembly comprising:
a substrate;
a composite-layered structure defining a conjunction plane, and one or more conductive-trace layers and one or more optical-trace layers arranged either or both of over and beneath the conjunction plane; wherein the optical-trace layer defines a plurality of optical traces, and the conductive-trace layer defines a plurality of conductive traces; and
a bonding layer adhesive between the substrate and the composite-layered structure.

2. The substrate assembly as claimed in claim 1, wherein the one or ones of the conductive-trace layers and the one or ones of the optical-trace layers are mixed in a coplanar manner; or either of the conductive-trace layer and the optical-trace layer is over the conjunction plane, and the other is beneath the conjunction plane.

3. The substrate assembly as claimed in claim 1, wherein some of the conductive-trace layers construct a redistribution layer (RDL); at least part of the trace width of one of the conductive-trace layer is no greater than 10 μm.

4. The substrate assembly as claimed in claim 1, further defining a supportive-substrate layer along the conjunction plane.

5. The substrate assembly as claimed in claim 4, wherein the conductive-trace layer(s) is/are arranged over the supportive-substrate layer; the optical-trace layer(s) is/are arranged over the supportive-substrate layer; or the conductive-trace layer(s) and the optical-trace layer(s) are mixed in a coplanar manner and arranged over the supportive-substrate layer.

6. The substrate assembly as claimed in claim 4, wherein materials of the supportive-substrate layer includes adhesion, polyimide, or a combination thereof.

7. The substrate assembly as claimed in claim 1, wherein the substrate is at least 100 mm by 100 mm in planar size.

8. The substrate assembly as claimed in claim 1, wherein the substrate is a glass substrate, a ceramic substrate, a bismaleimide triazin laminated (BT) substrate, a fiberglass-reinforced epoxy-laminated (FR4) substrate, a build-up film, or a Rogers substrate, a polyimide substrate, or any combination containing any substrate mentioned-above.

9. The substrate assembly as claimed in claim 1, further defining a plurality of passages, which are formed of either or both of the conductive-trace layers and the optical-trace layers for electrical connection or optical communication in a perpendicular direction to the substrate, wherein the passages pass through the bonding layer, or further through the substrate.

10. The substrate assembly as claimed in claim 4, further defining a plurality of passages, which are formed of either or both of the conductive-trace layers and the optical-trace layers for electrical connection or optical communication in a perpendicular direction to the substrate; wherein the passages pass through the bonding layer and the supportive-substrate layer, or further through the substrate.

11. The substrate assembly as claimed in claim 1, wherein some of the optical traces of the optical-trace layer extend in a first direction along the composite-layered structure, and some of the optical traces of the optical-trace layer extend in a second direction along the composite-layered structure; the first direction is non-parallel with the second direction.

12. The substrate assembly as claimed in claim 1, wherein the substrate, the optical-trace layers, and the conductive-trace layers define a coefficient of thermal expansion; and a difference of CTE between any of the substrate, the optical-trace layers, and the conductive-trace layers is no greater than 30 ppm/° C.

13. The substrate assembly as claimed in claim 4, wherein the substrate, the optical-trace layers, the conductive-trace layers, and the supportive-substrate layer define a coefficient of thermal expansion; and a difference of CTE between any of the substrate, the optical-trace layers, and the conductive-trace layers is no greater than 30 ppm/° C.

14. A substrate assembly comprising:
a substrate;
a composite-layered structure defining a conjunction plane, and one or more optical-trace layers arranged over and beneath the conjunction plane; wherein the optical-trace layer defines a plurality of optical traces; and
a bonding layer adhesive between the substrate and the composite-layered structure.

15. The substrate assembly as claimed in claim 14, further defining a supportive-substrate layer along the conjunction plane.

16. The substrate assembly as claimed in claim 14, wherein the substrate and the optical-trace layers define a coefficient of thermal expansion; and a difference of CTE between any of the substrate and the optical-trace layers is no greater than 30 ppm/° C.

17. An electronic device comprising:
a substrate assembly as claimed in claim 1; and
a plurality of semiconductor components arranged on the composite-layered structure of the substrate assemblies; wherein some of the semiconductor components electrically connect the conductive-trace layers, and some of the semiconductor components optically communicate with the optical-trace layers.

18. The electronic device as claimed in claim 17, wherein one or ones of the semiconductor components are SoCs (System-on-Chip), or/and HBMs (high bandwidth memory).

19. The electronic device as claimed in claim 17, wherein at least some of the semiconductor components are stacked over one another.

20. The electronic device as claimed in claim 17, wherein in addition to the electrical connection, there is an optical communication between corresponding two of the composite-layered structure, the substrate, and the semiconductor components.
